(19) United States
(12) Patent Application Publication
(10) Pub. No.: US 2026/0033176 A1
(43) Pub. Date: Jan. 29, 2026

(54) Display Substrate, Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Huijuan YANG, Beijing (CN); Hongwei MA, Beijing (CN); Xiaoqing SHU, Beijing (CN); Biao LIU, Beijing (CN); Zhiwen CHU, Beijing (CN); Yi ZHANG, Beijing (CN)

(21) Appl. No.: 18/994,082

(22) PCT Filed: May 14, 2024
(86) PCT No.: PCT/CN2024/093028

§ 371 Date: Jan. 14, 2025

(30) Foreign Application Priority Data
Jun. 21, 2023 (CN) 202310745478.6

(51) Int. Cl. H10K 59/131; H10K 59/12; H10K 59/122; H10K 59/35

(52) U.S. Cl. CPC H10K 59/131; H10K 59/1201; H10K 59/122; H10K 59/353

(57) ABSTRACT

A display substrate includes a drive structure layer and a light emitting structure layer disposed on the base substrate; the drive structure layer includes a plurality of circuit units, a circuit unit includes a pixel drive circuit; the light emitting structure layer includes a plurality of light emitting units, a light emitting units includes an anode and a pixel definition layer, the anode is connected to a pixel drive circuit of a corresponding circuit unit, the pixel definition layer is provided with a pixel opening exposing the anode; the drive structure layer further includes at least two signal lines extending along a first direction, an orthographic projection of the pixel opening on the base substrate is at least partially overlapped with orthographic projections of the at least two signal lines on the base substrate.

### CROSS-REFERENCE TO RELATED APPLICATIONS

This application is a national stage application of PCT Application No. PCT/CN2024/093028 which is filed on May 14, 2024 and claims priority to Chinese Patent Application No. 202310745478.6 filed to the CNIPA on Jun. 21, 2023 and entitled “Display Substrate and Preparation method Therefor, and Display Apparatus”, contents of which should be construed as being incorporated into the present application by reference.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In one aspect, the present disclosure provides a display substrate including a drive structure layer disposed on a base substrate and a light emitting structure layer disposed on a side of the drive structure layer away from the base substrate; the drive structure layer includes a plurality of circuit units, and at least one circuit unit includes a pixel drive circuit; the light emitting structure layer includes a plurality of light emitting units, at least one light emitting unit includes an anode and a pixel definition layer disposed on a side of the anode away from the base substrate, the anode is connected to a pixel drive circuit of a corresponding circuit unit, and the pixel definition layer is provided with a pixel opening exposing the anode; the drive structure layer further includes at least two signal lines extending along a first direction, in at least one pixel opening, an orthographic projection of the pixel opening on the base substrate is at least partially overlapped with orthographic projections of the at least two signal lines on the base substrate, and the at least two signal lines are respectively located at two sides of a geometric center of the pixel opening in a second direction, and the first direction and the second direction intersect.

In an exemplary implementation mode, the at least two signal lines include a first connection line and a power supply connection line, the power supply connection line is connected to a data signal line extending along the second direction, the power supply connection line is connected to a first power supply line extending along the second direction, and the data signal line and the first power supply line are connected to the pixel drive circuits; in the at least one pixel opening, the first connection line and the power supply connection line are disposed symmetrically with respect to a center line, and the center line is a straight line extending along the first direction and passing through a geometric center of the pixel opening.

In an exemplary implementation mode, in the at least one pixel opening, the pixel opening includes a first end at a side of the power supply connection line away from the center line and a second end at a side of the first connection line away from the center line, the power supply connection line includes a first edge on a side away from the center line, the first connection line includes a second edge on a side away from the center line, the first end has a first distance from the first edge, the second end has a second distance from the second edge, and a ratio of the first distance to the second distance is 0.9 to 1.1.

In an exemplary implementation mode, the drive structure layer further includes a second connection line extending along the second direction, the second connection line is connected to the first connection line, in the at least one pixel opening, an orthographic projection of the second connection line on the base substrate is at least partially overlapped with an orthographic projection of the geometric center of the pixel opening on the base substrate.

In an exemplary implementation mode, the orthographic projection of the pixel opening on the base substrate at least partially overlaps orthographic projections of two data signal lines on the base substrate, the second connection line is disposed between the two data signal lines, and the two data signal lines are disposed symmetrically with respect to the second connection line.

In an exemplary implementation mode, the orthographic projection of the pixel opening on the base substrate is at least partially overlapped with orthographic projections of two first power supply lines on the base substrate, the second connection line and the two data signal lines are disposed between the two first power supply lines, and the two first power supply lines are disposed symmetrically with respect to the second connection line.

In an exemplary implementation mode, the drive structure layer further includes a plurality of power supply connection lines extending along the first direction and a plurality of first power supply lines extending along the second direction, and the power supply connection lines and the first power supply lines are connected to form a grid connecting structure for transmitting a first power supply signal.

In an exemplary implementation mode, on a plane perpendicular to the display substrate, the drive structure layer includes a plurality of conductive layers sequentially disposed on the base substrate, and the power supply connection lines and the first power supply lines are disposed in different conductive layers.

In an exemplary implementation mode, the at least two signal lines include a first connection line and the power supply connection line, and the power supply connection line and the first connection line are disposed in a same conductive layer.

In an exemplary implementation mode, the drive structure layer further includes a second connection line, the second connection line is connected to the first connection line, the first connection line is connected to a data signal line, and the data signal line, the first power supply line, and the second connection line are disposed in a same conductive layer.

In an exemplary implementation mode, the plurality of light emitting units includes a red light emitting unit emitting red light, a blue light emitting unit emitting blue light, a first green light emitting unit emitting green light, and a second green light emitting unit emitting green light, the red light emitting unit includes at least a first anode and a first pixel opening exposing the first anode, the blue light emitting unit includes at least a second anode and a second pixel opening exposing the second anode, the first green light emitting unit includes at least a third anode and a third pixel opening exposing the third anode, the second green light emitting unit includes at least a fourth anode and a fourth pixel opening exposing the fourth anode; for at least one of the first pixel opening and the second pixel opening, and the at least two signal lines are respectively located at two sides of a geometric center of the pixel opening in second direction.

In an exemplary implementation mode, the drive structure layer further includes a plurality of anode pads, for at least one of the third pixel opening and the fourth pixel opening, an orthographic projection of the pixel opening on the base substrate is at least partially overlapped with an orthographic projection of the anode pads on the base substrate.

In an exemplary implementation mode, for at least one of the third pixel opening and the fourth pixel opening, an orthographic projection of the pixel opening on the base substrate is within a range of an orthographic projection of the anode pads on the base substrate.

In an exemplary implementation mode, the drive structure layer further includes a first power supply line, and the anode pads are connected to the first power supply line.

In another aspect, a display apparatus is also provided in the present disclosure, and the display apparatus includes the display substrate described above.

In another aspect, the present disclosure further provides a preparation method for a display substrate, including:

Forming a drive structure layer on a base substrate, wherein the drive structure layer includes a plurality of circuit units and at least two signal lines extending along a first direction, at least one circuit unit includes a pixel drive circuit;

Forming a light emitting structure layer on the drive structure layer, wherein the light emitting structure layer includes a plurality of light emitting units, at least one light emitting unit includes an anode and a pixel definition layer disposed on a side of the anode away from the base substrate, the anode is connected to a pixel drive circuit of a corresponding circuit unit, the pixel definition layer is provided with a pixel opening exposing the anode; and

The drive structure layer further includes at least two signal lines extending along a first direction, in at least one pixel opening, an orthographic projection of the pixel opening on the base substrate is at least partially overlapped with an orthographic projection of the at least two signal lines on the base substrate, and the at least two signal lines are respectively located at two sides of a geometric center of the pixel opening in a second direction, and the first direction and the second direction intersect.

Other aspects of the present disclosure may be comprehended after the drawings and the detailed descriptions are read and understood.

### BRIEF DESCRIPTION OF DRAWINGS

Accompanying drawings are used to provide understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a structure of a display apparatus.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is an equivalent circuit diagram of a pixel drive circuit.

FIG. 6 is a schematic diagram of a planar structure of a display substrate according to an exemplary embodiment of the present disclosure.

FIG. 7 is a schematic diagram after a pattern of a shield layer is formed according to an embodiment of the present disclosure.

FIGS. 8A and 8B are schematic diagrams after a pattern of a first semiconductor layer is formed according to an embodiment of the present disclosure.

FIGS. 9A and 9B are schematic diagrams after a pattern of a first conductive layer is formed according to an embodiment of the present disclosure.

FIGS. 10A and 10B are schematic diagrams after a pattern of a second conductive layer is formed according to an embodiment of the present disclosure.

FIGS. 11A and 11B are schematic diagrams after a pattern of a second semiconductor layer is formed according to an embodiment of the present disclosure.

FIGS. 12A and 12B are schematic diagrams after a pattern of a third conductive layer is formed according to an embodiment of the present disclosure.

FIG. 13 is a schematic diagram after a pattern of a sixth insulation layer is formed according to an embodiment of the present disclosure.

FIGS. 14A and 14B are schematic diagrams after a pattern of a fourth conductive layer is formed according to an embodiment of the present disclosure.

FIG. 15 is a schematic diagram after a pattern of a first planarization layer is formed according to an embodiment of the present disclosure.

FIGS. 16A and 16B are schematic diagrams after a pattern of a fifth conductive layer is formed according to an embodiment of the present disclosure.

FIG. 17 is a schematic diagram after a pattern of a second planarization layer is formed according to an embodiment of the present disclosure.

FIGS. 18A and 18B are schematic diagrams after a pattern of a sixth conductive layer is formed according to an embodiment of the present disclosure.

FIG. 19 is a schematic diagram after a pattern of a third planarization layer is formed according to an embodiment of the present disclosure.

FIG. 20 is a schematic diagram after a pattern of an anode conductive layer is formed according to an embodiment of the present disclosure.

FIG. 21 is a schematic diagram after a pattern of a pixel definition layer is formed according to an embodiment of the present disclosure.

FIG. 22 is a schematic diagram of a positional relationship between pixel openings and a signal line according to the present disclosure.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” means that a boundary is not defined so strictly and numerical values within process and measurement error ranges are allowed.

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (El to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation mode, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines DATA1, D2, D3, . . . , and Dn using the grayscale value and the control signal that are received from the timing controller. For example, the data driver may sample the grayscale value using the clock signal and apply a data voltage corresponding to the grayscale value to the data signal lines DATA1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines EM1, E2, E3, . . . , and Eo. For example, the light emitting driver may sequentially provide an emission signal with an off-level pulse to the light emitting signal lines EM1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation mode, the pixel array may be arranged on a display substrate.

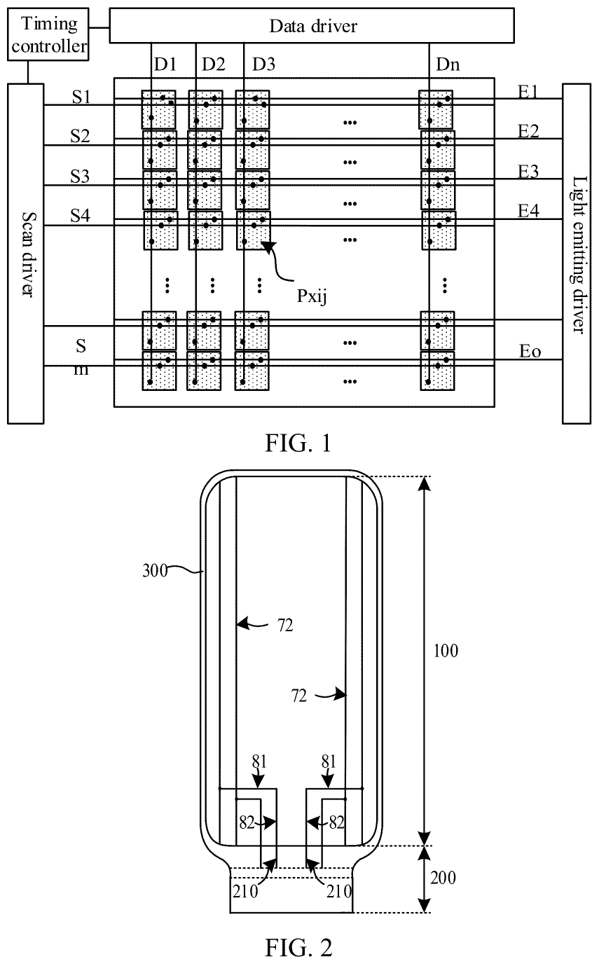

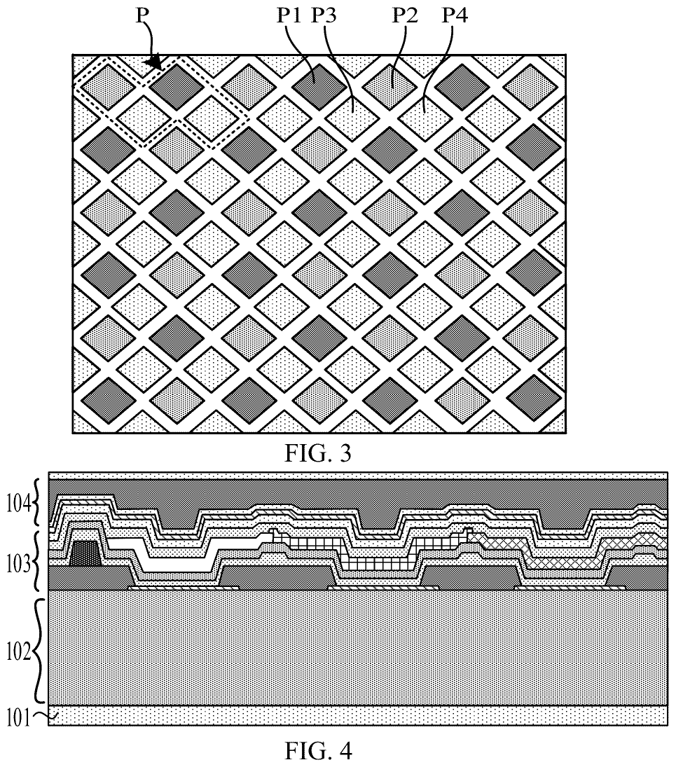

FIG. 2 is a schematic diagram of a structure of a display substrate. As shown in FIG. 2, the display substrate may include a display region 100, a bonding region 200 located on a side of the display region 100, and a bezel region 300 located on another side of the display region 100. In an exemplary embodiment, the display region 100 may be a planar region including a plurality of sub-pixels that form a pixel array. The plurality of sub-pixels is configured to display a dynamic picture or a still image, and the display region 100 may be referred to as an active area (AA for short). In an exemplary implementation mode, the display substrate may be a flexible substrate, so that the display substrate may be deformable, for example, be curled, bent, folded, or rolled.

In exemplary implementations, the bonding region 200 may include a fan-out region, a bending region, a drive chip region, and a bonding pin region that are disposed sequentially along a direction away from the display region 100. The fan-out region is connected to the display region 100 and may at least include a plurality of data lead-out lines parallel to each other. The bending region is connected to the fan-out region and may include a composite insulation layer provided with a groove, and is configured to enable the bonding region to be bent to a back of the display region. The drive chip region may at least include an Integrated Circuit (IC for short) and is configured to be connected to the plurality of data fan-out lines. The bonding pin region may at least include a plurality of bonding pads, and is configured to be bonded to and connected to an external Flexible Printed Circuit (FPC for short).

In an exemplary implementation mode, the bezel region 300 may include a circuit region, a power supply line region, a crack dam region, and a cutting region which are sequentially disposed along the direction away from the display region 100. The circuit region is connected to the display region 100 and may at least include a gate drive circuit which is connected to a scan signal line and a light emitting signal line of a pixel drive circuit in the display region 100. The power supply line region is connected to the circuit region and may at least include a bezel power supply lead, wherein the bezel power supply lead extends along a direction parallel to an edge of the display region and is connected to a cathode in the display region 100. The crack dam region is connected to the power supply line region and may at least include a plurality of cracks provided on the composite insulation layer. The cutting region is connected to the crack dam region and may at least include a cutting groove arranged on the composite insulation layer, and the cutting groove is configured that a cutting equipment can implement cutting along cutting grooves respectively after all film layers of the display substrate are manufactured.

In an exemplary implementation mode, a fan-out region in the bonding region 200 and a power supply line region in the bezel region 300 may be provided with at least one isolation dam, the isolation dam may extend along a direction parallel to the edge of the display region to form an annular structure surrounding the display region 100, wherein the edge of the display region is an edge of a side of the display region close to the bonding region, or the bezel region.

In an exemplary implementation mode, the display region 100 further includes a plurality of data signal lines 72 extending along a second direction Y, a plurality of first connection lines 81 extending along a first direction X, and a plurality of second connection lines 82 extending along the second direction Y. The data signal lines 72 are respectively connected to multiple pixel drive circuits in one pixel column and are configured to provide data signals to the connected pixel drive circuits. The first ends of the plurality of first connection lines 81 are correspondingly connected to the plurality of data signal lines 72, the second ends of the plurality of first connection lines 81 are correspondingly connected to the first ends of the plurality of second connection lines 82, the second ends of the plurality of second connection lines 82 are correspondingly connected to the first ends of the plurality of data lead lines 210 in the bonding region 200, and the second ends of the plurality of data lead lines 210, after extending along the second direction Y and crossing the bending region, are connected with the drive chip of the drive chip region, so that the drive chip applies data signals supplied by the drive chip to the data signal line 72 through the data lead line 210, the first connection line 81, and the second connection line 82. In an exemplary implementation mode, the first connection lines 81 and the second connection lines 82 may constitute data connection lines, a structure in which data connection lines are located in the display region (Fanout in AA, FIAA for short) is formed. Since the data connection lines are disposed in the display region, a width of a lower bezel can be reduced and a screen-to-body ratio is increased.

FIG. 3 is a schematic diagram of a planar structure of a display region in a display substrate. As shown in FIG. 2, the display substrate may include a plurality of pixel units P arranged in a matrix. At least one pixel unit P may include a first sub-pixel Pl emitting light of a first color, a second sub-pixel P2 emitting light of a second color, a third sub-pixel P3 and a fourth sub-pixel P4 which emit light of a third color. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. A light emitting unit in each sub-pixel is connected with a pixel drive circuit of the sub-pixel where the light emitting unit is located, and is configured to emit light with corresponding brightness in response to a current output by the pixel drive circuit of the sub-pixel where the light emitting unit is located.

In an exemplary implementation mode, the first sub-pixel PI may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation mode, a sub-pixel may be in a shape of a rectangle, a diamond, a pentagon, or a hexagon. The four sub-pixels may be arranged in a manner to form a diamond to form an RGBG pixel arrangement. In other exemplary implementations, the four sub-pixels may be arranged side by side horizontally, side by side vertically, or in a manner to form a square, which is not limited in the present disclosure.

In an exemplary implementation mode, a pixel unit may include three sub-pixels, and the three sub-pixels may be arranged side by side horizontally, side by side vertically, or in a delta-shaped arrangement, which is not limited here in the present disclosure.

FIG. 4 is a schematic diagram of cross-sectional structure of a display region in a display substrate, illustrating a structure of four sub-pixels in the display region. As shown in FIG. 3, on a plane perpendicular to the display substrate, the display substrate may include a drive circuit layer 102 arranged on a base substrate 101, a light emitting structure layer 103 arranged on a side of the drive circuit layer 102 away from the base substrate 101, and an encapsulation structure layer 104 arranged on a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 may include a plurality of circuit units, each of which may at least include a pixel drive circuit composed of a plurality of transistors and a storage capacitor. The light emitting structure layer 103 may include a plurality of light emitting units, each light emitting unit may at least include an anode, a pixel definition layer, an organic emitting layer, and a cathode, the anode is connected with the pixel drive circuit, the organic emitting layer is connected with the anode, the cathode is connected with the organic emitting layer, and the organic emitting layer emits light of a corresponding color under drive of the anode and the cathode. The encapsulation structure layer 104 may include a first encapsulation structure layer, a second encapsulation structure layer, and a third encapsulation structure layer that are stacked. The first encapsulation structure layer and the third encapsulation structure layer may be made of an inorganic material, the second encapsulation structure layer may be made of an organic material, and the second encapsulation structure layer is arranged between the first encapsulation structure layer and the third encapsulation structure layer to form a laminated structure of inorganic material/organic material/inorganic material and ensure that external moisture cannot enter the light emitting structure layer 103.

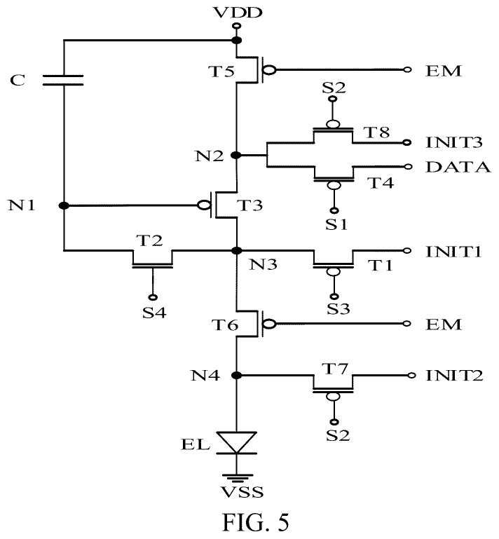

FIG. 5 is an equivalent circuit diagram of a pixel drive circuit. In an exemplary embodiment, the pixel drive circuit may have a structure of 3TIC, 4TIC, 5TIC, 5T2C, 6TIC, 7T1C, or 8TIC. As shown in FIG. 5, the pixel drive circuit may include eight transistors (a first transistor T1 to an eighth transistor T8) and one storage capacitor C, and the pixel drive circuit is connected to 10 signal lines (a first scan signal line S1, a second scan signal line S2, a third scan signal line S3, a fourth scan signal line S4, a light emitting signal line EM, a first initial signal line INIT1, a second initial signal line INIT2, a third initial signal line INIT3, a data signal line DATA and a first power supply line VDD), respectively.

In an exemplary implementation mode, the pixel drive circuit may include a first node N1, a second node N2, a third node N3, and a fourth node N4. The first node N1 is connected to a first electrode of the second transistor T2, a gate electrode of the third transistor T3 and a first terminal of the storage capacitor C, respectively, the second node N2 is connected to a first electrode of the third transistor T3, a second electrode of the fourth transistor T4, a second electrode of the fifth transistor T5 and a second electrode of the eighth transistor T8, respectively, the third node N3 is connected to a second electrode of the first transistor T1, a second electrode of the second transistor T2, a second electrode of the third transistor T3 and a first electrode of the sixth transistor T6, the fourth node N4 is connected to a second electrode of the sixth transistor T6 and a second electrode of the seventh transistor T7, respectively, and the fourth node N4 is also connected to an anode of the light emitting device EL.

In an exemplary implementation mode, the first terminal of the storage capacitor C is connected with the first node N1, and a second terminal of the storage capacitor C is connected with the first power supply line VDD.

In an exemplary implementation mode, the first transistor TI may be referred to as a first initialization transistor, a gate electrode of the first transistor T1 is connected to the third scan signal line S3, a first electrode of the first transistor T1 is connected to the first initial signal line INIT1, and a second electrode of the first transistor T1 is connected to the third node N3. The second transistor T2 may be referred to as a compensation transistor, a gate electrode of the second transistor T2 is connected to the fourth scan signal line S4, a first electrode of the second transistor T2 is connected to the first node N1, and a second electrode of the second transistor T2 is connected to the third node N3. The third transistor T3 may be referred to as a drive transistor, a gate electrode of the third transistor T3 is connected to the first node N1, i.e., a gate electrode of the third transistor T3 is connected to a first terminal of the storage capacitor C, a first electrode of the third transistor T3 is connected to the second node N2, and a second electrode of the third transistor T3 is connected to the third node N3. The fourth transistor T4 may be referred to as a data writing transistor, a gate electrode of the fourth transistor T4 is connected to the first scan signal line S1, a first electrode of the fourth transistor T4 is connected to the data signal line DATA, and a second electrode of the fourth transistor T4 is connected to the second node N2. The fifth transistor T5 may be referred to as a first light emitting control transistor, a gate electrode of the fifth transistor T5 is connected to the light emitting signal line EM, a first electrode of the fifth transistor T5 is connected to the first power supply line VDD, and a second electrode of the fifth transistor T5 is connected to the second node N2. The sixth transistor T6 may be referred to as a second light emitting control transistor, a gate electrode of the sixth transistor T6 is connected to the light emitting signal line EM, a first electrode of the sixth transistor T6 is connected to the third node N3, and a second electrode of the sixth transistor T6 is connected to the fourth node N4. The seventh transistor T7 may be referred to as a second initialization transistor, a gate electrode of the seventh transistor T7 is connected to the second scan signal line S2, a first electrode of the seventh transistor T7 is connected to the second initial signal line INIT2, and a second electrode of the seventh transistor T7 is connected to the fourth node N4. The eighth transistor T8 may be referred to as a third initialization transistor, a gate electrode of the eighth transistor T8 is connected to the second scan signal line S2, a first electrode of the eighth transistor T8 is connected to the third initial signal line INIT3, and a second electrode of the eighth transistor T8 is connected to the second node N2.

In an exemplary implementation mode, the light emitting device EL may be an OLED including an anode (first electrode), an organic emitting layer, and a cathode (second electrode) that are stacked, or may be a QLED including an anode (first electrode), a quantum dot emitting layer, and a cathode (second electrode) that are stacked.

In an exemplary implementation mode, a first electrode of the light emitting device EL is connected to the fourth node N4, and a second electrode of the light emitting device EL is connected to a second power supply line VSS, the signal of the second power supply line VSS is a continuously supplied low-level signal, and the signal of the first power supply line VDD is a continuously supplied high-level signal.

In an exemplary implementation mode, the first transistor T1 to the eighth transistor T8 may be P-type transistors or N-type transistors. Use of a same type of transistors in a pixel drive circuit may simplify a process flow, reduce a process difficulty of a display panel, and improve a product yield. In some possible implementations, the first transistor T1 to the eighth transistor T8 may include P-type transistors and N-type transistors.

In an exemplary implementation mode, the first transistor T1 to the eighth transistor T8 may employ a low temperature poly-silicon transistor, or may employ an oxide transistor, or may employ both of the low temperature poly-silicon transistor and the metal oxide transistor. Low Temperature Poly-Silicon (LTPS for short) is adopted for an active layer of a low temperature polysilicon transistor and a metal oxide semiconductor (Oxide) is adopted for an active layer of a metal oxide transistor. The low temperature polysilicon transistor has advantages such as a high migration rate and fast charging, and the oxide transistor has advantages such as a low drain current. The low temperature polysilicon transistor and the metal oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

In an exemplary implementation mode, the second transistor T2 may be a metal oxide transistor, and the first transistor T1, the third transistor T3 to the eighth transistor T8 may be low-temperature polysilicon transistors.

A display substrate is provided in an exemplary embodiment of the present disclosure. In an exemplary implementation mode, on a plane perpendicular to the display substrate, the display substrate may include a drive structure layer arranged on a base substrate and a light emitting structure layer arranged on a side of the drive structure layer away from the base substrate. On a plane parallel to the display substrate, the display substrate may at least include a display region, a bonding region on a side of the display region, and a bezel region on the other side of the display region. In an exemplary embodiment, a drive structure layer of a display region may include multiple circuit units forming multiple unit rows and multiple unit columns, and at least one circuit unit may include a pixel drive circuit configured to output a corresponding current to a connected light emitting device. The light emitting structure layer of the display region may include a plurality of light emitting units, at least one light emitting unit may include a light emitting device, the light emitting device is connected with a pixel drive circuit of a corresponding circuit unit, and the light emitting device is configured to emit light with corresponding brightness in response to a current outputted by the connected pixel drive circuit.

In an exemplary implementation mode, circuit units mentioned in the present disclosure refer to regions divided according to pixel drive circuits, and light emitting units mentioned in the present disclosure refer to regions divided according to light emitting devices. In an exemplary implementation mode, a position and a shape of an orthographic projection of a light emitting unit on the base substrate may correspond to a position and a shape of an orthographic projection of a circuit unit on the base substrate, or a position and a shape of an orthographic projection of a light emitting unit on the base substrate may not correspond to a position and a shape of an orthographic projection of a circuit unit on the base substrate.

In an exemplary implementation mode, the drive structure layer further includes at least two signal lines extending along the first direction, and at least one light emitting device may include an anode disposed on a side of the drive structure layer away from the base substrate and a pixel definition layer disposed on a side of the anode away from the base substrate, the pixel definition layer is provided with a pixel opening exposing a surface of the anode. In at least one pixel opening, an orthographic projection of the pixel opening on the base substrate is at least partially overlapped with orthographic projections of the at least two signal lines extending along the first direction on the base substrate, and the at least two signal lines extending along the first direction may be respectively located at two sides of a geometric center of the pixel opening in the second direction, and the first direction and the second direction intersect.

In an exemplary implementation mode, the at least two signal lines include a first connection line and a power supply connection line, the power supply connection line is connected to a data signal line extending along the second direction, the power supply connection line is connected to a first power supply line extending along the second direction, and the data signal line and the first power supply line are connected to the pixel drive circuits; in the at least one pixel opening, the first connection line and the power supply connection line are disposed symmetrically with respect to a center line, and the center line is a straight line extending along the first direction and passing through a geometric center of the pixel opening.

In an exemplary implementation mode, in the at least one pixel opening, the pixel opening includes a first end at a side of the power supply connection line away from the center line and a second end at a side of the first connection line away from the center line, the power supply connection line includes a first edge on a side away from the center line, the first connection line includes a second edge on a side away from the center line, the first end has a first distance from the first edge, the second end has a second distance from the second edge, and a ratio of the first distance to the second distance is 0.9 to 1.1.

In an exemplary implementation mode, the drive structure layer further includes a second connection line extending along the second direction, the second connection line is connected to the first connection line. In the at least one pixel opening, an orthographic projection of the second connection line on the base substrate is at least partially overlapped with an orthographic projection of the geometric center of the pixel opening on the base substrate.

In an exemplary implementation mode, the orthographic projection of the pixel opening on the base substrate at least partially overlaps orthographic projections of two data signal lines on the base substrate, the second connection line is disposed between the two data signal lines, and the two data signal lines are disposed symmetrically with respect to the second connection line.

In an exemplary implementation mode, the orthographic projection of the pixel opening on the base substrate is at least partially overlapped with orthographic projections of two first power supply lines on the base substrate, the second connection line and the two data signal lines are disposed between the two first power supply lines, and the two first power supply lines are disposed symmetrically with respect to the second connection line.

In an exemplary implementation mode, the drive structure layer further includes a plurality of power supply connection lines extending along the first direction and a plurality of first power supply lines extending along the second direction, and the power supply connection lines and the first power supply lines are connected to form a grid connecting structure for transmitting a first power supply signal.

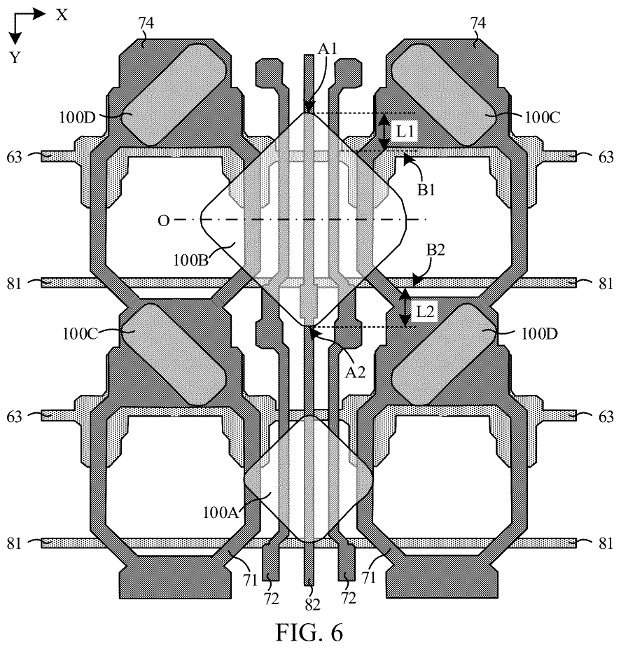

FIG. 6 is a schematic diagram of a planar structure of a display substrate according to an exemplary embodiment of the present disclosure. In an exemplary implementation mode, the display substrate may include at least a drive structure layer disposed on the base substrate and a light emitting structure layer disposed on a side of the drive structure layer away from the base substrate. On a plane parallel to the display substrate, the drive structure layer may include a plurality of circuit units, and the light emitting structure layer may include a plurality of light emitting units.

In an exemplary implementation mode, the plurality of circuit units may form a plurality of unit rows and a plurality of unit columns, the plurality of circuit units in each unit row are sequentially arranged along the first direction X, and the plurality of unit rows are sequentially arranged along a second direction Y, constituting a circuit unit array arranged in an array, and a circuit unit may include at least a pixel drive circuit. The plurality of light emitting units may form a plurality of light emitting rows and a plurality of light emitting columns, a plurality of light emitting units in each light emitting row are sequentially disposed along the first direction X, and the plurality of light emitting rows are sequentially disposed along the second direction Y constituting a light emitting unit array arranged in an array, a light emitting unit may include at least an anode and a pixel definition layer covering the anode, the anode is connected with a pixel drive circuit of a corresponding circuit unit, and a pixel opening exposing the anode is provided on the pixel definition layer. In an exemplary implementation mode, the first direction X intersects with the second direction Y.

As shown in FIG. 6, the drive structure layer may further include a power supply connection line 63 and a first connection line 81 in which a main body portion extends along the first direction X, a first power supply line 71, a data signal line 72, and a second connection line 82 in which a main body portion extends along the second direction Y. In the present disclosure, “A extends in a B direction” refers to that A may include a main portion and a secondary portion connected to the main portion, wherein the main portion is a line, a line segment, or a strip-shaped body, the main portion extends in the B direction, and a length of the main portion extending in the B direction is greater than a length of the secondary portion extending in another direction. In following description, “A extends in a B direction” means “a main body portion of A extends in a B direction”.

In an exemplary implementation mode, the second connection line 82 is connected to the first connection line 81, the first connection line 81 is connected to the data signal line 72, the data signal line 72 is connected to a plurality of pixel drive circuits of one unit column, the first connection line 81 and the second connection line 82 are configured to provide data signals to the connected data signal line 72, forming a FIAA structure, and the data signal line 72 is configured to provide a data signal to the connected pixel drive circuits.

In an exemplary implementation mode, the first power supply line 71 is connected to a plurality of pixel drive circuits of one unit column, and the first power supply line 71 is configured to provide a first power supply signal to the connected pixel drive circuits. A plurality of power supply connection lines 63 and a plurality of first power supply lines 71 constitute a grid connecting structure for transmitting the first power supply signal on the display substrate.

As illustrated in FIG. 6, the plurality of light emitting units included in the light emitting structure layer may include a red light emitting unit that emits red light, a blue light emitting unit that emits blue light, a first green light emitting unit that emits green light, and a second green light emitting unit that emits green light. In an exemplary implementation mode, the red light emitting unit may include at least a first anode and a first pixel opening 100A exposing the first anode, the blue light emitting unit may include at least a second anode and a second pixel opening 100B exposing the second anode, the first green light emitting unit may include at least a third anode and a third pixel opening 100C exposing the third anode, and the second green light emitting unit may include at least a fourth anode and a fourth pixel opening 100D exposing the fourth anode.

In an exemplary implementation mode, the power supply connection line 63 and the first connection line 81 extending along the first direction X may be located at two sides of a geometric center of the first pixel opening 100A in the second direction Y, respectively, and/or the power supply connection line 63 and the first connection line 81 extending along the first direction X may be located at two sides of a geometric center of the second pixel opening 100B in the second direction Y, respectively.

In an exemplary implementation mode, the power supply connection line 63 and the first connection line 81 may be disposed symmetrically with respect to a center line of a pixel opening. For example, the power supply connection line 63 and the first connection line 81 may be disposed symmetrically with respect to the center line of the first pixel opening 100A, which is a straight line extending along the first direction X and passing through the geometric center of the first pixel opening 100A. As another example, the power supply connection line 63 and the first connection line 81 may be disposed symmetrically with respect to the center line of the second pixel opening 100B, which is a straight line extending along the first direction X and passing through the geometric center of the second pixel opening 100B.

In an exemplary implementation mode, for at least one of the first pixel opening 100A and the second pixel opening 100B, a distance between the power supply connection line 63 and one end of the pixel opening may be substantially the same as a distance between the first connection line 81 and the other end of the pixel opening.

In an exemplary implementation mode, taking the second pixel opening 100B as an example, the second pixel opening 100B has a center line O, a first end A1 located at a side of the power supply connection line 63 away from the center line O, and a second end A2 located at a side of the first connection line 81 away from the center line O, the power supply connection line 63 has a first edge B1 on a side away from the center line O, and the first connection line 81 has a second edge B2 on a side away from the center line O. There is a first distance L1 between the first end A1 and the first edge B1, there is a second distance L2 between the second end A2 and the second edge B2, and a ratio of the first distance L1 to the second distance L2 may be about 0.9 to 1.1.

In an exemplary implementation mode, the ratio of the first distance L1 to the second distance L2 may be about 1.0.

In an exemplary implementation mode, orthographic projections of the first power supply line 71, the data signal line 72, and the second connection line 82 extending along the second direction Y on the base substrate are at least partially overlapped with an orthographic projection of the first pixel opening 100A on the base substrate, and/or orthographic projections of the first power supply line 71, the data signal line 72, and the second connection line 82 extending along the second direction Y on the base substrate are at least partially overlapped with an orthographic projection of the second pixel opening 100B on the base substrate.

In an exemplary implementation mode, an orthographic projection of the second connection line 82 on the base substrate is at least partially overlapped with an orthographic projection of a geometric center of the first pixel opening 100A on the base substrate, and/or an orthographic projection of the second connection line 82 on the base substrate is at least partially overlapped with an orthographic projection of a geometric center of the second pixel opening 100B on the base substrate.

In an exemplary implementation mode, an orthographic projection of the first pixel opening 100A on the base substrate is at least partially overlapped with orthographic projections of two data signal lines 72 on the base substrate, and/or an orthographic projection of the second pixel opening 100B on the base substrate is at least partially overlapped with the orthographic projections of the two data signal lines 72 on the base substrate. The second connection line 82 may be disposed between the two data signal lines 72, and the two data signal lines 72 may be disposed symmetrically with respect to the second connection line 82.

In an exemplary implementation mode, an orthographic projection of the first pixel opening 100A on the base substrate is at least partially overlapped with orthographic projections of two first power supply lines 71 on the base substrate, and/or an orthographic projection of the second pixel opening 100B on the base substrate is at least partially overlapped with the orthographic projections of the two first power supply lines 71 on the base substrate. The second connection line 82 and the two data signal lines 72 may be disposed between the two first power supply lines 71, and the two first power supply lines 71 may be disposed symmetrically with respect to the second connection line 82.

In an exemplary implementation mode, the drive structure layer may further include a plurality of anode pads 74, and an anode pad 74 is connected to a first power supply line 71.

In an exemplary implementation mode, anode pads 74 in some of two adjacent circuit units in unit row may be of an interconnected integral structure.

In an exemplary implementation mode, an orthographic projection of the third pixel opening 100C on the base substrate is at least partially overlapped with an orthographic projection of the anode pad 74 on the base substrate, and/or an orthographic projection of the fourth pixel opening 100D on the base substrate is at least partially overlapped with an orthographic projection of the anode pad 74 on the base substrate.

In an exemplary implementation mode, an orthographic projection of the third pixel opening 100C on the base substrate may be within a range of an orthographic projection of the anode pad 74 on the base substrate, and/or an orthographic projection of the fourth pixel opening 100D on the base substrate may be within a range of an orthographic projection of the anode pad 74 on the base substrate.

In an exemplary implementation mode, on a plane perpendicular to the display substrate, the drive structure layer includes a plurality of conductive layers disposed sequentially on the base substrate, the first connection line 81 and the second connection line 82 may be disposed in different conductive layers, the power supply connection line 63 and the first power supply line 71 may be disposed in different conductive layers, the power supply connection line 63 and the first connection line 81 may be disposed in a same conductive layer, the first power supply line 71, the data signal line 72, and the second connection line 82 may be disposed in a same conductive layer, the second connection line 82 may be connected to the first connection line 81 through a via, the first connection line 81 may be connected to the data signal line 72 through a via, and the first power supply line 71 may be connected to the power supply connection line 63 through a via.

In an exemplary implementation mode, the plurality of conductive layers may include at least a first source-drain metal layer, a second source-drain metal layer, and a third source-drain metal layer sequentially disposed in a direction away from the base substrate, the power supply connection line 63 and the first power supply line 71 may be disposed in the second source-drain metal layer, and the first power supply line 71, the data signal line 72, and the second connection line 82 may be disposed in the third source-drain metal layer.

In an exemplary implementation mode, the anode pad 74 and the first power supply line 71 may be disposed in a same conductive layer, and may be of an interconnected integral structure.

In an exemplary implementation mode, a pixel drive circuit includes at least a storage capacitor and a plurality of transistors, and the plurality of transistors may include a first transistor, a second transistor, a third transistor, a fourth transistor, a fifth transistor, a sixth transistor, a seventh transistor, and an eighth transistor, the second transistor is an oxide transistor, and the first transistor, the third transistor to the eighth transistor are low-temperature polysilicon transistors.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation mode, taking eight circuit units (2 unit rows and 4 unit columns) as an example, the preparation process of the drive circuit layer may include the following acts.

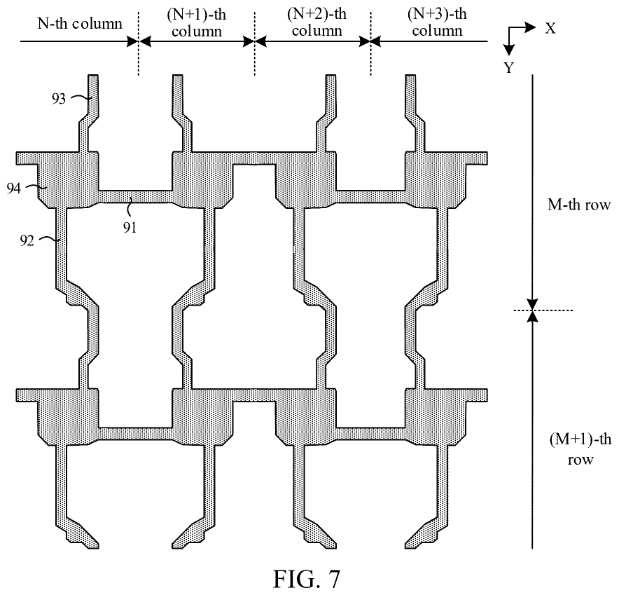

(1) A pattern of a shield layer is formed. In an exemplary implementation mode, forming the pattern of the shield layer may include: depositing a shield thin film on a base substrate, patterning the shield thin film through a patterning process to form the pattern of the shield layer on the base substrate, as shown in FIG. 7.

In an exemplary implementation mode, a pattern of a shield layer of each circuit unit may at least include a first shield connection line 91, a second shield connection line 92, a third shield connection line 93, and a shield electrode 94.

In an exemplary implementation mode, the shield electrode 94 may be in a shape of a rectangle, corners of the rectangle may be provided with chamfers. The first shield connection line 91 may be in a shape of a straight line extending along a first direction X, and the first shield connection line 91 may be disposed on a side of the shield electrode 94 in the first direction X and connected with the shield electrode 94. The second shield connection line 92 may be in a shape of a bending line extending along a second direction Y, and the second shield connection line 92 may be disposed on a side of the shield electrode 94 in the second direction Y and connected with the shield electrode 94. The third shield connection line 93 may be in a shape of a bending line extending along the second direction Y, and the third shield connection line 93 may be disposed on a side of the shield electrode 94 in an opposite direction of the second direction Y and connected with the shield electrode 94.

In an exemplary implementation mode, the first shield connection line 91 of each circuit unit is connected with a shield electrode 94 of an adjacent circuit unit in the first direction X, so that shield layers in one unit row are connected into a whole to form an interconnected integral structure.

In an exemplary implementation mode, the second shield connection line 92 of each circuit unit is connected with a third shield connection line 93 of an adjacent circuit unit in the second direction Y, so that the second shield connection line 92, the third shield connection line 93, and the shield electrode 94 in one unit column are connected into a whole to form an interconnected integral structure.

In an exemplary implementation mode, shield layers in a unit row and a unit column are connected into a whole, which may ensure that the shield layers in the display substrate have a same potential, which is beneficial to improving uniformity of a panel, avoiding poor display of the display substrate, and ensuring a display effect of the display substrate.

In an exemplary implementation mode, the shield layers of adjacent unit columns may be mirror symmetrical with respect to a column dividing line, which may be a straight line located between adjacent unit columns and extending along the second direction Y. For example, the shield layer of an N-th column and the shield layer of an (N+1)-th column may be mirror symmetrical with respect to the column dividing line, the shield layer of an (N+1)-th column and the shield layer of an (N+2)-th column may be mirror symmetrical with respect to the column dividing line, and the shield layer of an (N+2)-th column and the shield layer of an (N+3)-th column may be mirror symmetrical with respect to the column dividing line. In an exemplary implementation mode, shapes of shield layers in a plurality of unit rows may be substantially the same.

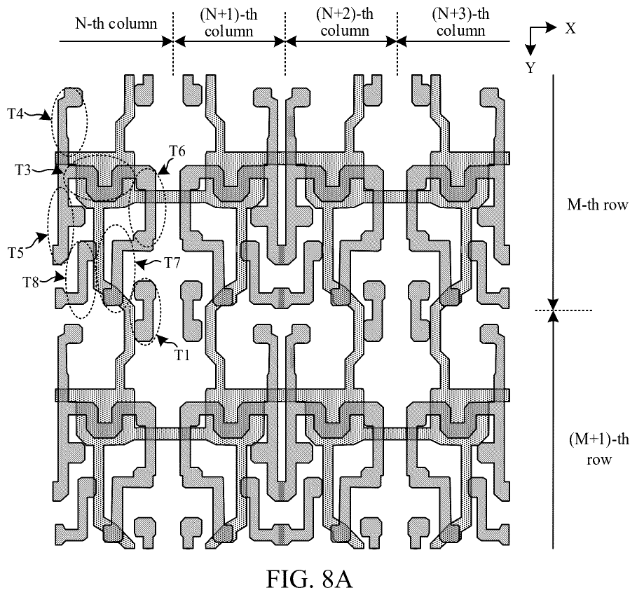

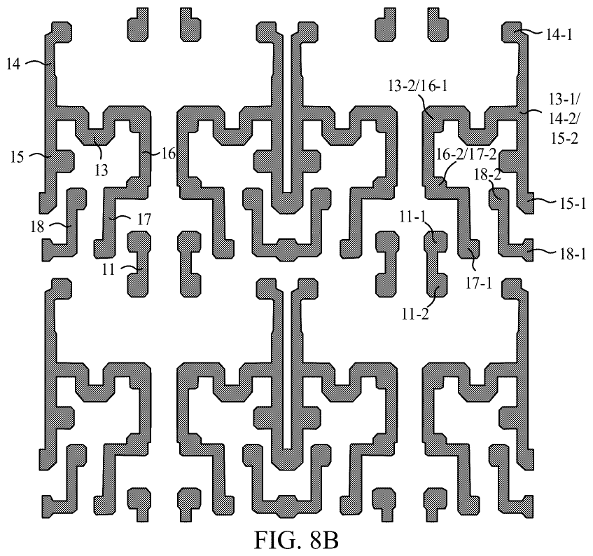

(2) A pattern of a first semiconductor layer is formed. In an exemplary embodiment, forming a pattern of a first semiconductor layer may include: sequentially depositing a first insulation thin film and a first semiconductor thin film on the base substrate, patterning the first semiconductor thin film through a patterning process to form a first insulation layer covering the shield layer, and a pattern of a first semiconductor layer disposed on the first insulation layer, as shown in FIG. 8A and FIG. 8B, and FIG. 8B is a schematic plan view of the first semiconductor layer in FIG. 8A.

In an exemplary implementation mode, the pattern of the first semiconductor layer of each circuit unit may include at least a first active layer 11 of the first transistor T1, a third active layer 13 of the third transistor T3 to an eighth active layer 18 of the eighth transistor T8, and the third active layer 13 to the seventh active layer 17 are of an interconnected integral structure, and the first active layer 11 and the eighth active layer 18 are separately disposed.

In an exemplary implementation mode, an orthographic projection of the third active layer 13 on the base substrate at least partially overlaps an orthographic projection of the shield electrode 94 on the base substrate.

In the first direction X, the first active layer 11 and the sixth active layer 16 may be located on a side of the third active layer 13 in the present circuit unit in the first direction X, and the fourth active layer 14 and the fifth active layer 15 may be located on a side of the third active layer 13 in the present circuit unit in an opposite direction of the first direction X. In the second direction Y, the fourth active layer 14 may be located at a side of the third active layer 13 in the present circuit unit in an opposite direction of the second direction Y, and the first active layer 11, the fifth active layer 15, the sixth active layer 16, the seventh active layer 17 and the eighth active layer 18 may be located at a side of the third active layer 13 in the present circuit unit in the second direction Y.

In an exemplary implementation mode, the third active layer 13 may be in a shape of an inverted “Ω”, the first active layer 11, the fourth active layer 14, the fifth active layer 15, and the sixth active layer 16 may be shaped in an “I” shape, and the seventh active layer 17 and the eighth active layer 18 may be shaped in an “L” shape.

In an exemplary implementation mode, the first active layer 11, the third active layer 13 to the eighth active layer 18 may each include a first region, a second region, and a channel region located between the first region and the second region. In an exemplary embodiment, the first region 13-1 of the third active layer may simultaneously serve as the second region 14-2 of the fourth active layer and the second region 15-2 of the fifth active layer, the second region 13-2 of the third active layer may serve as the first region 16-1 of the sixth active layer, the second region 16-2 of the sixth active layer may serve as the second region 17-2 of the seventh active layer, the first region 11-1 of the first active layer, the second region 11-2 of the first active layer, the first region 14-1 of the fourth active layer, the first region 15-1 of the fifth active layer, the first region 17-1 of the seventh active layer, the first region 18-1 of the eighth active layer and the second region 18-2 of the eighth active layer may be separately disposed.

In an exemplary implementation mode, in one unit row, the fifth active layers in some of two adjacent circuit units may be an interconnected integral structure. For example, the first region 15-1 of the fifth active layer in an (N−1)-th column and the first region 15-1 of the fifth active layer in an N-th column are connected to each other, the first region 15-1 of the fifth active layer in an (N+1)-th column and the first region 15-1 of the fifth active layer in an (N+2)-th column are connected to each other, and the first region 15-1 of the fifth active layer in an (N+3)-th column and the first region 15-1 of the fifth active layer in an (N+4)-th column are connected to each other. Since the first region of the fifth active layer in each circuit unit is configured to be connected to a first power supply line formed subsequently, by setting the first regions of the fifth active layers of adjacent circuit units to be interconnected to be of an integral structure, the first electrodes of the fifth transistors T5 of adjacent circuit units can be guaranteed to have a same potential, which is beneficial for improving the uniformity of the panel, avoiding poor display of the display substrate and ensuring the display effect of the display substrate.

In an exemplary implementation mode, in one unit row, the eighth active layers in some of two adjacent circuit units may be of an interconnected integral structure. For example, the first region 18-1 of the eighth active layer in an (N−1)-th column and the first region 18-1 of the eighth active layer in an N-th column are connected to each other, the first region 18-1 of the eighth active layer in an (N+1)-th column and the first region 18-1 of the eighth active layer in an (N+2)-th column are connected to each other, and the first region 18-1 of the eighth active layer in an (N+3)-th column and the first region 18-1 of the eighth active layer in an (N+4)-th column are connected to each other. Since the first region 18-1 of the eighth active layer in each circuit unit is configured to be connected to the third initial signal line formed subsequently, by forming the first regions 18-1 of the eighth active layers of adjacent circuit units into an interconnected integral structure, the first electrodes of the eighth transistors of adjacent circuit units can be guaranteed to have a same potential, which is beneficial for improving the uniformity of the panel, avoiding poor display of the display substrate and ensuring the display effect of the display substrate.

In an exemplary implementation mode, the first active layer 11 may be disposed between two adjacent unit columns, the first region 11-1 of the first active layer may be located in the circuit units of an M-th row, the second region 11-2 of the first active layer may be located in the circuit units of an (M+1)-th row, and M may be a positive integer greater than or equal to 1.

In an exemplary implementation mode, the first semiconductor layers of adjacent unit columns may be mirror symmetrical with respect to a column dividing line. For example, the first semiconductor layer of an N-th column and the first semiconductor layer of an (N+1)-th column may be mirror symmetrical with respect to the column dividing line, the first semiconductor layer of the (N+1)-th column and the first semiconductor layer of an (N+2)-th column may be mirror symmetrical with respect to the column dividing line, and the first semiconductor layer of the (N+2)-th column and the first semiconductor layer of an (N+3)-th column may be mirror symmetrical with respect to the column dividing line. In an exemplary implementation mode, shapes of first semiconductor layers in a plurality of unit rows may be substantially the same.

In an exemplary implementation mode, the first semiconductor layer may be made of poly Silicon (p-Si), i.e., the third transistor to the seventh transistor are LTPS transistors. In an exemplary implementation mode, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.

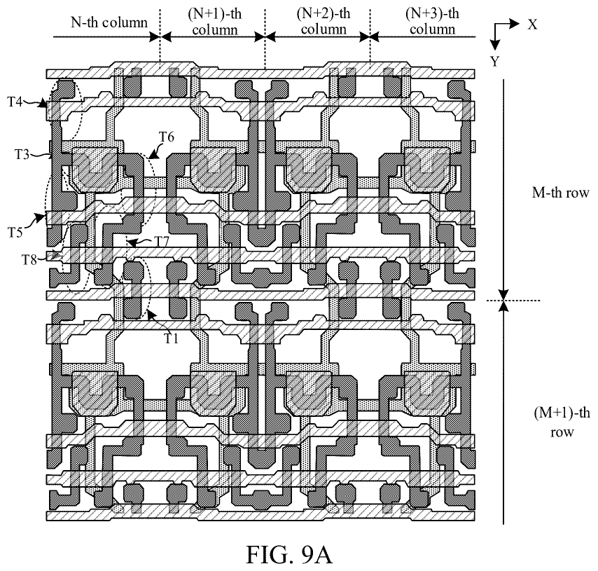

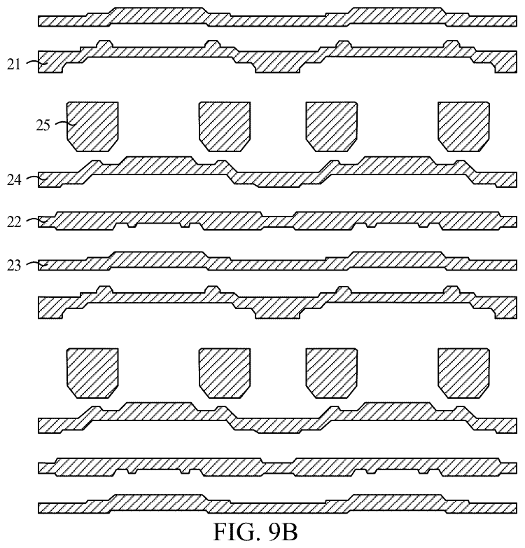

(3) A pattern of a first conductive layer is formed. In an exemplary implementation mode, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers the pattern of the first semiconductor layer and form the pattern of the first conductive layer arranged on the second insulation layer, as shown in FIG. 9A and FIG. 9B. FIG. 9B is a schematic plan view of the first conductive layer in FIG. 9A. In an exemplary implementation mode, the first conductive layer may be referred to as a first gate metal (GATE1) layer.

In an exemplary implementation mode, the pattern of the first conductive layer of each circuit unit at least includes: a first scan signal line 21, a second scan signal line 22, a third scan signal line 23, a light emitting signal line 24, and a first plate 25 of a storage capacitor.

In an exemplary implementation mode, the first plate 25 may be in a shape of a rectangle, and a chamfer may be provided at a corner of the rectangle. An orthographic projection of the first plate 25 on the base substrate is at least partially overlapped with an orthographic projection of the third active layer of the third transistor T3 on the base substrate. In an exemplary implementation mode, the first plate 25 may serve as one plate of the storage capacitor and a gate electrode of the third transistor T3 simultaneously.

In an exemplary implementation mode, the first scan signal line 21 may be in a shape of a bending line in which a main portion extends along the first direction X, the first scan signal line 21 may be located at a side of the first plate 25 in an opposite direction of the second direction Y, and a region where the first scan signal line 21 overlaps with the fourth active layer may serve as a gate electrode of the fourth transistor T4.

In an exemplary implementation mode, the second scan signal line 22 may be in a shape of a bending line in which a main portion extends along the first direction X, the second scan signal line 22 may be located on a side of the first plate 25 in the second direction Y, a region where the second scan signal line 22 overlaps the seventh active layer may serve as the gate electrode of the seventh transistor T7, and a region where the second scan signal line 22 overlaps the eighth active layer may serve as the gate electrode of the eighth transistor T8.

In an exemplary implementation mode, the third scan signal line 23 may be in a shape of a bending line in which a main body portion extends along the first direction X, the third scan signal line 23 may be located at a side of the second scan signal line 22 away from the first plate 25, and a region where the third scan signal line 23 is overlapped with the first active layer may serve as the gate electrode of the first transistor T1.

In an exemplary implementation mode, the light emitting signal line 24 may be in a shape of a bending line in which a main portion extends along the first direction X, the light emitting signal line 24 may be located at a side of the second scan signal line 22 close to the first plate 25, a region where the light emitting signal line 24 overlaps the fifth active layer may serve as the gate electrode of the fifth transistor T5, and a region where the light emitting signal line 24 overlaps the sixth active layer may serve as the gate electrode of the sixth transistor T6.

In an exemplary implementation mode, the first scan signal line 21, the second scan signal line 22, the third scan signal line 23, and the light emitting signal line 24 may be designed with unequal widths, and the widths are dimensions in the second direction Y, so that not only a layout of a pixel structure may be facilitated, but also a parasitic capacitance between signal lines may be reduced, which is not limited here in the present disclosure.

In an exemplary implementation mode, the first scan signal line 21, the second scan signal line 22, the third scan signal line 23, and the light emitting signal line 24 may include a region overlapping with the first semiconductor layer and a region not overlapping with the first semiconductor layer, and a width of the signal line in the region overlapping with the first semiconductor layer may be greater than a width of the signal line in the region not overlapping with the first semiconductor layer.

In an exemplary implementation mode, first conductive layers of adjacent unit columns may be mirror symmetric with respect to a column dividing line. For example, the first conductive layer of an N-th column and the first conductive layer of an (N+1)-th column may be mirror symmetrical with respect to the column dividing line, the first conductive layer of the (N+1)-th column and the first conductive layer of an (N+2)-th column may be mirror symmetrical with respect to the column dividing line, and the first conductive layer of the (N+2)-th column and the first conductive layer of an (N+3)-th column may be mirror symmetrical with respect to the column dividing line. In an exemplary implementation mode, shapes of first conductive layers in a plurality of unit rows may be substantially the same.

In an exemplary implementation mode, after the pattern of the first conductive layer is formed, a conductive treatment may be performed on the first semiconductor layer by using the first conductive layer as a shield. A region of the first semiconductor layer, which is shielded by the first conductive layer, forms channel regions of the first transistor T1, the third transistor T3 to the eighth transistor T8, and a region of the first semiconductor layer, which is not shielded by the first conductive layer, is made to be conductive, that is, first regions and second regions of the first transistor T1, the third transistor T3 to the eighth transistor T8 are all made to be conductive.

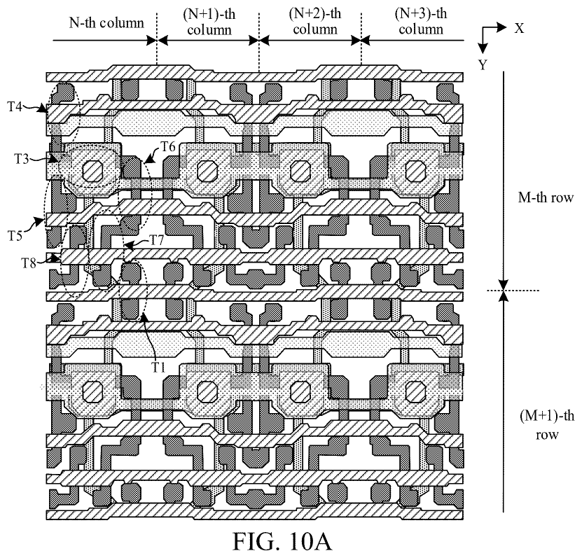

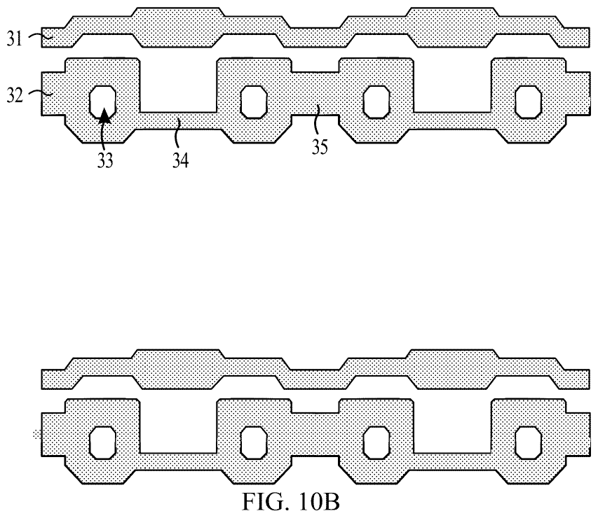

(4) A pattern of a second conductive layer is formed. In an exemplary implementation mode, forming the pattern of the second conductive layer may include: depositing sequentially a third insulation thin film and a second conductive thin film on the base substrate on which the aforementioned patterns are formed, and the second conductive thin film is patterned through a patterning process to form a third insulation layer that covers the first conductive layer, and the pattern of the second conductive layer arranged on the third insulation layer, as shown in FIG. 10A and FIG. 10B. FIG. 10B is a schematic plan diagram of the second conductive layer in FIG. 10A. In an exemplary implementation mode, the second conductive layer may be referred to as a second gate metal (GATE2) layer.

In an exemplary implementation mode, the pattern of the second conductive layer of each circuit unit at least includes a shield line 31 and a second plate 32 of the storage capacitor.

In an exemplary implementation mode, the shield line 31 may be in a shape of a line in which a main portion extends along the first direction X, the shield line 31 may be located between the first scan signal line 21 and the first plate 25, and the shield line 31 is configured as a shield layer of the second transistor T2, shielding the channel region of the second transistor T2, ensuring the electrical performance of the oxide second transistor T2, and is also configured to serve as a bottom gate electrode of the second transistor T2.

In an exemplary implementation mode, the shield line 31 may be designed with non-equal widths, which can not only facilitate the layout of the pixel structure, but also reduce the parasitic capacitance between the signal lines.

In an exemplary implementation mode, a profile of the second plate 32 may be in a shape of a rectangle, a chamfer may be provided at a corner of the rectangle, an orthographic projection of the second plate 32 on the base substrate is at least partially overlapped with an orthographic projection of the first plate 25 on the base substrate, the second plate 32 may serve as anther plate of the storage capacitor, and the first plate 25 and the second plate 32 form the storage capacitor of the pixel drive circuit.

In an exemplary implementation mode, the second plate 32 is provided with an opening 33 which may have a rectangular shape and may be located in the middle of the second plate 32, so that the second plate 32 forms an annular structure. The opening 33 exposes the third insulation layer covering the first plate 25, and an orthographic projection of the first plate 25 on the base substrate contains an orthographic projection of the opening 33 on the base substrate. In an exemplary implementation mode, the opening 33 is configured to accommodate a thirteenth via to be formed subsequently, and the thirteenth via is located within the opening 33 and exposes the first plate 25, so that a first connection electrode to be formed subsequently is connected to the first plate 25.

In an exemplary implementation mode, the second plates 32 in two adjacent circuit units in a unit row may be an interconnected integral structure. A second plate 32 of the N-th column and a second plate 32 of the (N+1)-th column are connected with each other through a first connection strip 34. For another example, a second plate 32 of the (N+1)-th column and a second plate 32 of the (N+2)-th column may be connected with each other through a second connection strip 35. Since a second plate 32 in each circuit unit is connected with a first power supply line to be formed subsequently, the second plates 32 of adjacent circuit units are connected with each other to form an integral structure, the second plates in the integral structure may be reused as a power supply signal line, so that a plurality of second plates in a unit row may be ensured to be have a same potential, which is beneficial for improving uniformity of the display substrate, avoiding poor display of the display substrate and ensuring a display effect of the display substrate.

In an exemplary implementation mode, the length and width of the first connection strip 34 and the second connection strip 35 may be different, and the first connection strip 34 and the second connection strip 35 may be staggered in the second direction.

In an exemplary implementation mode, second conductive layers of adjacent unit columns may be mirror symmetric with respect to a column dividing line. For example, the second conductive layer of the N-th column and the second conductive layer of the (N+1)-th column may be mirror symmetrical with respect to the column dividing line, the second conductive layer of the (N+1)-th column and the second conductive layer of the (N+2)-th column may be mirror symmetrical with respect to the column dividing line, and the second conductive layer of the (N+2)-th column and the second conductive layer of the (N+3)-th column may be mirror symmetrical with respect to the column dividing line. In an exemplary implementation mode, shapes of second conductive layers in a plurality of unit rows may be substantially the same.

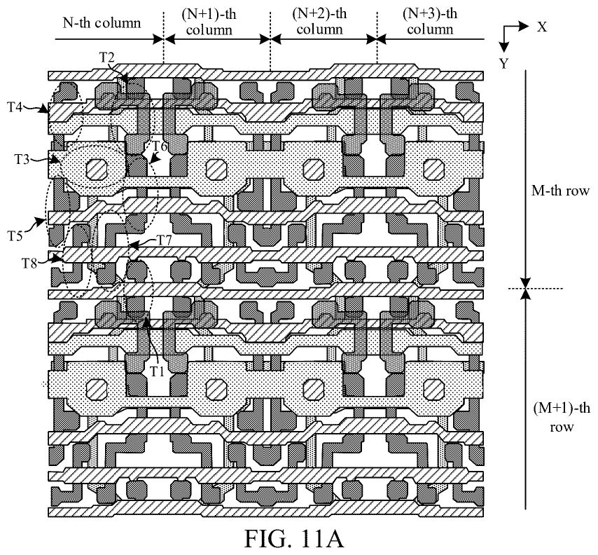

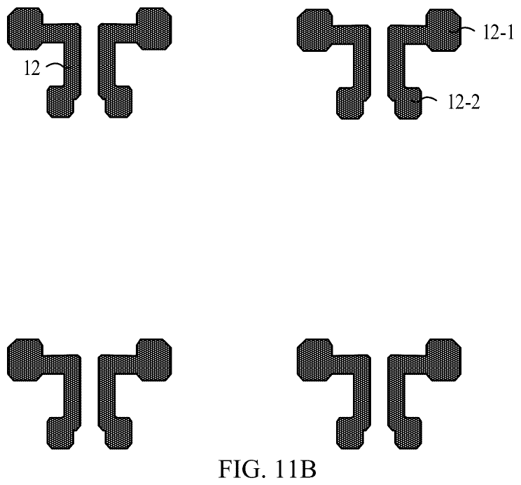

(5) A pattern of a second semiconductor layer is formed. In an exemplary implementation mode, forming the pattern of the second semiconductor layer may include: depositing a fourth insulation thin film and a second semiconductor thin film sequentially on the base substrate on which the above-mentioned patterns are formed, patterning the second semiconductor thin film through a patterning process to form a fourth insulation layer that covers the base substrate, and the pattern of the second semiconductor layer arranged on the fourth insulation layer, as shown in FIG. 11A and FIG. 11B. FIG. 11B is a schematic plan view of the second conductive layer in FIG. 11A.

In an exemplary implementation mode, the pattern of the second semiconductor layer of each circuit unit at least includes a second active layer 12 of the second transistor T2.

In an exemplary implementation mode, a shape of the second active layer 12 may be an “L” shape, and an orthographic projection of the second active layer 12 on the base substrate is at least partially overlapped with an orthographic projection of the shield line 31 on the base substrate.

In an exemplary implementation mode, the first region 12-1 of the second active layer may be located at a side of the shield line 31 away from the second plate 32, and the second region 12-2 of the second active layer may be located at a side of the shield line 31 close to the second plate 32.

In an exemplary implementation mode, second semiconductor layers of adjacent unit columns may be mirror symmetric with respect to a column dividing line. For example, the second semiconductor layer of the N-th column and the second semiconductor layer of the (N+1)-th column may be mirror symmetrical with respect to the column dividing line, the second semiconductor layer of the (N+1)-th column and the second semiconductor layer of the (N+2)-th column may be mirror symmetrical with respect to the column dividing line, and the second semiconductor layer of the (N+2)-th column and the second semiconductor layer of the (N+3)-th column may be mirror symmetrical with respect to the column dividing line. In an exemplary implementation mode, shapes of second semiconductor layers in a plurality of unit rows may be substantially the same.

In an exemplary implementation mode, the second semiconductor layer may be made of an oxide, i.e., the eighth transistor T8 is an oxide transistor. In an exemplary implementation mode, the second semiconductor thin film may be made of Indium Gallium Zinc Oxide (IGZO), wherein electron mobility of the Indium Gallium Zinc Oxide (IGZO) is higher than that of amorphous silicon.

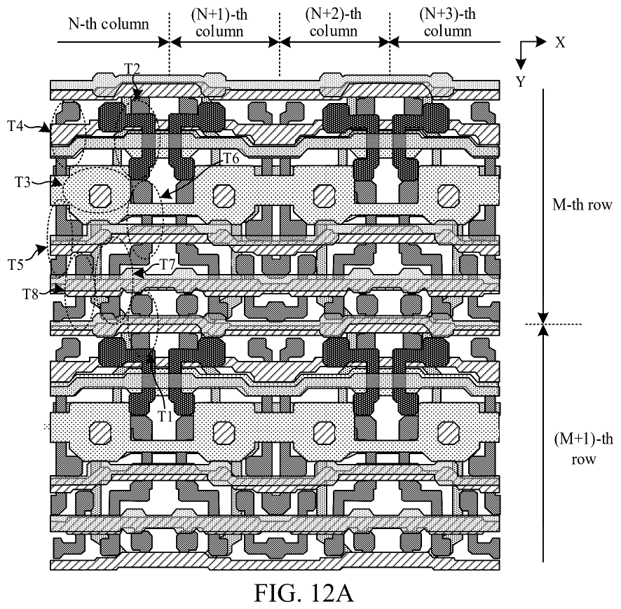

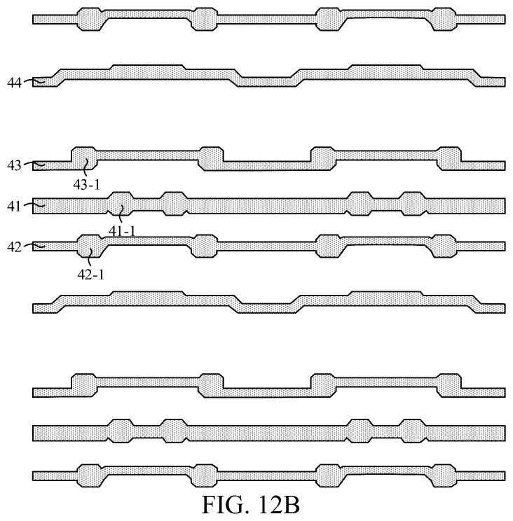

(6) A pattern of a third conductive layer is formed. In an exemplary implementation mode, forming the pattern of the third conductive layer may include: depositing a fifth insulation thin film and a third conductive thin film sequentially on the base substrate on which the aforementioned patterns are formed, and patterning the third conductive thin film through a patterning process to form a fifth insulation layer covering the second semiconductor layer, and the pattern of the third conductive layer arranged on the fifth insulation layer, as shown in FIG. 12A and FIG. 12B. FIG. 12B is a schematic plan view of the third conductive layer in FIG. 12A. In an exemplary implementation mode, the second conductive layer may be referred to as a third gate metal (GATE3) layer.

In an exemplary implementation mode, the pattern of the third conductive layer of each circuit unit at least includes a first initial signal line 41, a second initial signal line 42, a third initial signal line 43, and a fourth scan signal line 44.

In an exemplary implementation mode, the first initial signal line 41 may be in a shape of a bending line in which a main portion extends along the first direction X, the first initial signal line 41 may be located between the third scan signal line 23 and the light emitting signal line 24, a first initial connection block 41-1 is provided on the first initial signal line 41 of each circuit unit, and the first initial connection block 41-1 is configured to be connected to the first region of the first active layer through the seventh connection electrode formed subsequently.

In an exemplary implementation mode, the second initial signal line 42 may be in a shape of a bending line in which a main portion extends along the first direction X, the second initial signal line 42 may be located at a side of the first initial signal line 41 away from the second plate 32, a second initial connection block 42-1 is provided on the second initial signal line 42 of each circuit unit, and the second initial connection block 42-1 is configured to be connected to the first region of the seventh active layer through the eighth connection electrode formed subsequently.

In an exemplary implementation mode, the third initial signal line 43 may be in a shape of a bending line in which a main portion extends along the first direction X, the third initial signal line 43 may be located at a side of the first initial signal line 41 close to the second plate 32, a third initial connection block 43-1 is provided on the third initial signal line 43 of each circuit unit, and the third initial connection block 43-1 is configured to be connected to the first region of the eighth active layer through the ninth connection electrode formed subsequently.

In an exemplary implementation mode, the fourth scan signal line 44 may be in a shape of a line in which a main portion extends along the first direction X, the fourth scan signal line 44 may be located between the first scan signal line 21 and the first plate 25, an orthographic projection of the fourth scan signal line 44 on the base substrate at least partially overlaps an orthographic projection of the shield line 31 on the base substrate, and a region where the fourth scan signal line 44 overlaps the second active layer may serve as a gate electrode of the second transistor T2.

In an exemplary implementation mode, the fourth scan signal line 44 and the shield line 31 may be connected to the same signal source so that the shield line 31 may serve as a bottom gate electrode of the second transistor T2, and the fourth scan signal line 44 may serve as a top gate electrode of the second transistor T2 to form the second transistor T2 with a top gate and bottom gate structure.

In an exemplary implementation mode, third conductive layers of adjacent unit columns may be mirror symmetric with respect to a column dividing line. For example, the third conductive layer of the N-th column and the third conductive layer of the (N+1)-th column may be mirror symmetrical with respect to the column dividing line, the third conductive layer of the (N+1)-th column and the third conductive layer of the (N+2)-th column may be mirror symmetrical with respect to the column dividing line, and the third conductive layer of the (N+2)-th column and the third conductive layer of the (N+3)-th column may be mirror symmetrical with respect to the column dividing line. In an exemplary implementation mode, shapes of third conductive layers in a plurality of unit rows may be substantially the same.

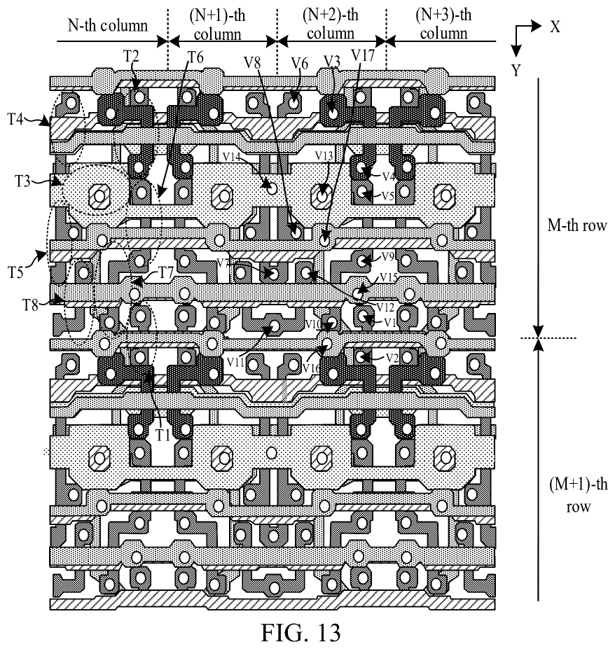

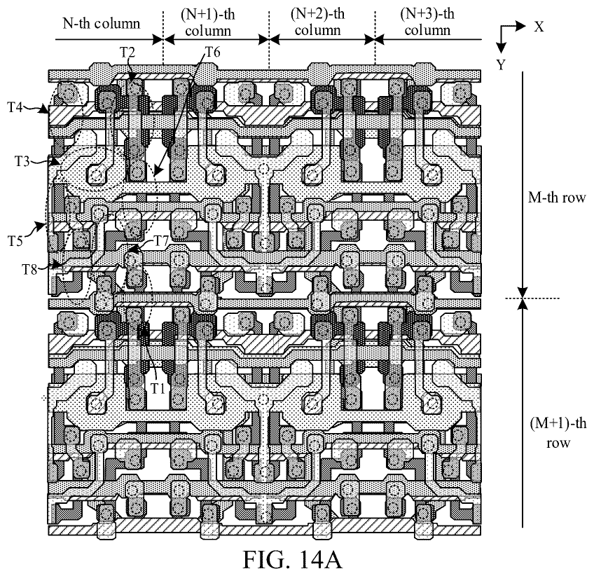

(7) A pattern of a sixth insulation layer is formed. In an exemplary implementation mode, forming the pattern of the sixth insulation layer may include: depositing a sixth insulation thin film on the base substrate on which the aforementioned patterns are formed, patterning the fifth insulation thin film using a patterning process to form a sixth insulation layer covering the third conductive layer, wherein a plurality of vias are arranged on the sixth insulation layer, as shown in FIG. 13.

In an exemplary implementation mode, the plurality of vias of each circuit unit includes at least a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, and a seventeenth via V17.

In an exemplary implementation mode, an orthographic projection of the first via V1 on the base substrate is within a range of an orthographic projection of the first region of the first active layer on the base substrate, the sixth insulation layer, the fifth insulation layer, the fourth insulation layer, the third insulation layer and the second insulation layer within the first via V1 are etched away to expose a surface of the first region of the first active layer, and the first via V1 is configured such that the seventh connection electrode to be formed subsequently is connected to the first region of the first active layer through the first via V1.

In an exemplary implementation mode, an orthographic projection of the second via V2 on the base substrate is within a range of an orthographic projection of a second region of the first insulation layer, the third insulation layer and the second insulation layer within the second via V2 are etched away to expose a surface of the second region of the first active layer, and the second via V2 is configured such that a second connection electrode to be formed subsequently is connected to the second region of the first active layer through the second via V2.

In an exemplary implementation mode, an orthographic projection of the third via V3 on the base substrate is within a range of an orthographic projection of a first region of the second active layer on the base substrate, the sixth insulation layer and the fifth insulation layer within the third via V3 are etched away to expose a surface of the first region of the second active layer, and the third via V3 is configured such that the first connection electrode to be formed subsequently is connected to the first region of the second active layer through the third via V3.

In an exemplary implementation mode, an orthographic projection of the fourth via V4 on the base substrate is within a range of an orthographic projection of a second region of the second active layer on the base substrate, the sixth insulation layer and the fifth insulation layer within the fourth via V4 are etched away to expose a surface of the second region of the second active layer, and the fourth via V4 is configured such that the second connection electrode to be formed subsequently is connected to the second region of the second active layer through the fourth via V4.

In an exemplary implementation mode, an orthographic projection of the fifth via V5 on the base substrate is within an orthographic projection of the second region of the third active layer (also the first region of the sixth active layer) on the base substrate, the sixth insulation layer, the fifth insulation layer, the fourth insulation layer, the third insulation layer and the second insulation layer within the fifth via V5 are etched away to expose a surface of the second region of the third active layer (also the first region of the sixth active layer), and the fifth via V5 is configured such that a subsequently formed second connection electrode is connected to the second region of the third active layer (also the first region of the sixth active layer) through the fifth via V5.

In an exemplary implementation mode, an orthographic projection of the sixth via V6 on the base substrate is within a range of an orthographic projection of a first region of the fourth insulation layer, the third insulation layer and the second insulation layer within the sixth via V6 are etched away to expose a surface of the first region of the fourth active layer, and the sixth via V6 is configured such that a third connection electrode to be formed subsequently is connected to the first region of the fourth active layer through the sixth via V6.

In an exemplary implementation mode, an orthographic projection of the seventh via V7 on the base substrate is within a range of an orthographic projection of a first region of the fifth active layer on the base substrate, the sixth insulation layer, the fifth insulation layer, the fourth insulation layer, the third insulation layer and the second insulation layer within the seventh via V7 are etched away to expose a surface of the first region of the fifth active layer, and the seventh via V7 is configured such that the fourth connection electrode to be formed subsequently is connected to the first region of the fifth active layer through the seventh via V7. In an exemplary implementation mode, since the first regions of the fifth active layers of some adjacent circuit units in a unit row are connected to each other, some adjacent circuit units may share a seventh via V7.

In an exemplary implementation mode, an orthographic projection of the eighth via V8 on the base substrate is within an orthographic projection of the second region of the fifth active layer on the base substrate, the sixth insulation layer, the fifth insulation layer, the fourth insulation layer, the third insulation layer and the second insulation layer within the eighth via V8 are etched away to expose a surface of the second region of the fifth active layer, and the eighth via V8 is configured such that a subsequently formed fifth connection electrode is connected to the second region of the fifth active layer (also the first region of the third active layer and the second region of the fourth active layer) through the eighth via V8.

In an exemplary implementation mode, an orthographic projection of the ninth via V9 on the base substrate is within an orthographic projection of the second region of the sixth active layer (also the second region of the seventh active layer) on the base substrate, the sixth insulation layer, the fifth insulation layer, the fourth insulation layer, the third insulation layer and the second insulation layer within the ninth via V9 are etched away to expose a surface of the second region of the sixth active layer (also the second region of the seventh active layer), and the ninth via V9 is configured such that a subsequently formed sixth connection electrode is connected to the second region of the sixth active layer (also the second region of the seventh active layer) through the ninth via V9.

In an exemplary implementation mode, an orthographic projection of the tenth via V10 on the base substrate is within a range of an orthographic projection of a first region of the seventh active layer on the base substrate, the sixth insulation layer, the fifth insulation layer, the fourth insulation layer, the third insulation layer and the second insulation layer within the tenth via V10 are etched away to expose a surface of the first region of the seventh active layer, and the tenth via V10 is configured such that an eighth connection electrode to be formed subsequently is connected to the first region of the seventh active layer through the tenth via V10.

In an exemplary implementation mode, an orthographic projection of an eleventh via V11 on the base substrate is within an orthographic projection of the first region of the eighth active layer on the base substrate, the sixth insulation layer, the fifth insulation layer, the fourth insulation layer, the third insulation layer and the second insulation layer within the eleventh via V11 are etched away to expose a surface of the first region of the eighth active layer, and the eleventh via V11 is configured such that a subsequently formed ninth connection electrode is connected to the first region of the eighth active layer through the eleventh via V11. In an exemplary implementation mode, since the first regions of the eighth active layers of some adjacent circuit units in a unit row are connected to each other, some adjacent circuit units may share an eleventh via V11.

In an exemplary implementation mode, an orthographic projection of the twelfth via V12 on the base substrate is within a range of an orthographic projection of a second region of the eighth active layer on the base substrate, the sixth insulation layer, the fifth insulation layer, the fourth insulation layer, the third insulation layer and the second insulation layer within the twelfth via V12 are etched away to expose a surface of the second region of the eighth active layer, and the twelfth via V12 is configured such that a fifth connection electrode to be formed subsequently is connected to the second region of the eighth active layer through the twelfth via V12.

In an exemplary implementation mode, an orthographic projection of the thirteenth via V13 on the base substrate is within a range of an orthographic projection of the opening 33 on the base substrate, the sixth insulation layer, the fifth insulation layer, the fourth insulation layer and the third insulation layer in the thirteenth via V13 are etched away to expose a surface of the first plate 25, and the thirteenth via V13 is configured such that the first connection electrode to be formed subsequently is connected to the first plate 25 through the thirteenth via V13.

In an exemplary implementation mode, an orthographic projection of the fourteenth via V14 on the base substrate is within a range of an orthographic projection of the second plate 32 on the base substrate, the sixth insulation layer, the fifth insulation layer and the fourth insulation layer in the fourteenth via V14 are etched away to expose a surface of the second plate 32, and the fourteenth via V14 is configured such that a subsequently formed fourth connection electrode is connected to the second plate 32 through the fourteenth via V14. In an exemplary implementation mode, since the second plates 32 of adjacent circuit units in a unit row are connected to each other, some adjacent circuit units in a unit row may share a fourteenth via V14.

In an exemplary implementation mode, an orthographic projection of the fifteenth via V15 on the base substrate is within a range of an orthographic projection of the first initial connection block 41-1 of the first initial signal line 41 on the base substrate, the sixth insulation layer in the fifteenth via V15 is etched away to expose a surface of the first initial connection block 41-1, and the fifteenth via V15 is configured such that the seventh connection electrode to be formed subsequently is connected to the first initial connection block 41-1 through the fifteenth via V15.

In an exemplary implementation mode, an orthographic projection of the sixteenth via V16 on the base substrate is within a range of an orthographic projection of the second initial connection block 42-1 of the second initial signal line 42 on the base substrate, the sixth insulation layer in the sixteenth via V16 is etched away to expose a surface of the second initial connection block 42-1, and the sixteenth via V16 is configured such that the eighth connection electrode to be formed subsequently is connected to the second initial connection block 42-1 through the sixteenth via V16.

In an exemplary implementation mode, an orthographic projection of the seventeenth via V17 on the base substrate is within a range of an orthographic projection of the third initial connection block 43-1 of the third initial signal line 43 on the base substrate, the sixth insulation layer in the seventeenth via V17 is etched away to expose a surface of the third initial connection block 43-1, and the seventeenth via V17 is configured such that the ninth connection electrode to be formed subsequently is connected to the third initial connection block 43-1 through the seventeenth via V17.

In an exemplary implementation mode, a plurality of vias of adjacent unit columns may be mirror symmetric with respect to a column dividing line, and shapes of a plurality of vias in a plurality of unit rows may be substantially the same.

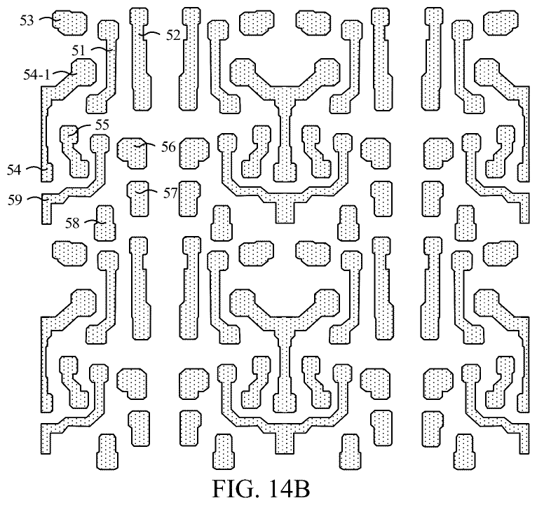

(8) A pattern of a fourth conductive layer is formed. In an exemplary implementation mode, forming the pattern of the fourth conductive layer may include: depositing a fourth conductive thin film on the base substrate on which the aforementioned patterns are formed, and patterning the fourth conductive thin film through a patterning process to form the fourth conductive layer arranged on the sixth insulation layer, as shown in FIG. 14A and FIG. 14B. FIG. 14B is a schematic plan view of the fourth conductive layer in FIG. 14A. In an exemplary implementation mode, the fourth conductive layer may be referred to as a first source drain metal (SD1) layer.

In an exemplary implementation mode, the fourth conductive layer of each circuit unit at least includes: a first connection electrode 51, a second connection electrode 52, a third connection electrode 53, a fourth connection electrode 54, a fifth connection electrode 55, a sixth connection electrode 56, a seventh connection electrode 57, an eighth connection electrode 58 and a ninth connection electrode 59.

In an exemplary implementation mode, the first connection electrode 51 may be in a shape of a bending line whose main portion extends in the second direction Y, a first end of the first connection electrode 51 is connected to the first region of the second active layer through the third via V3, and a second end of the first connection electrode 51, after extending along the second direction Y, is connected to the first plate 25 through the thirteenth via V13. In an exemplary implementation mode, since the first plate 25 simultaneously serves as the gate electrode of the third transistor T3, the first connection electrode 51 enables the first electrode of the second transistor T2, the gate electrode of the third transistor T3 and the first plate 25 to have a same potential to form a first node N1 of the pixel drive circuit.

In an exemplary implementation mode, the second connection electrode 52 may be in a shape of a bending line in which a main portion extends along the second direction Y, a first end of the second connection electrode 52 is connected to the second region of the first active layer through the second via V2, and a second end of the second connection electrode 52 extends in the second direction Y to be connected to the second region of the third active layer (also the first region of the sixth active layer) through the fifth via V5, and the portion between the first end and the second end of the second connection electrode 52 is connected to the second region of the second active layer through the fourth via V4. In an exemplary implementation mode, the second connection electrode 52 enables the second electrode of the first transistor T1, the second electrode of the second transistor T2, the second electrode of the third transistor T3, and the first electrode of the sixth transistor T6 to have a same potential to form a third node N3 of the pixel drive circuit.

In an exemplary implementation mode, the third connection electrode 53 may be in a shape of a block (such as a rectangle) and the third connection electrode 53 is connected to the first region of the fourth active layer through the sixth via V6. In an exemplary implementation mode, the third connection electrode 53 may serve as a first electrode of the fourth transistor T4, and the third connection electrode 53 is configured to be connected with an eleventh connection electrode formed subsequently.

In an exemplary implementation mode, the fourth connection electrode 54 may be in a shape of a bending line in which a main portion extends along the second direction Y, a first end of the fourth connection electrode 54 is connected to a first region of the fifth active layer through the seventh via V7, and a second end of the fourth connection electrode 54, after extending along an opposite direction of the second direction Y, is connected to the second plate 32 through the fourteenth via V14, thus realizing that a first electrode of the fifth transistor T5 in the circuit unit and the second plate 32 of the storage capacitor have the same potential.

In an exemplary implementation mode, the fourth connection electrode 54 may serve as the first electrode of the fifth transistor T5. A power supply connection block 54-1 is provided on the fourth connection electrode 54, the power supply connection block 54-1 is provided on a side of the second end of the fourth connection electrode 54 away from the first end, and the power supply connection block 54-1 is configured to be connected to the power supply connection line formed subsequently.

In an exemplary implementation mode, in one unit row, the fourth connection electrodes 54 in some of two adjacent circuit units may be of an interconnected integral structure, which may ensure that the first electrodes of the fifth transistors T5 and the second plates 32 of the storage capacitors of the adjacent circuit units have a same potential, which is beneficial to improving uniformity of a panel, avoiding poor display of the display substrate, and ensuring a display effect of the display substrate. For example, the fourth connection electrode 54 of the (N−1)-th column and the fourth connection electrode 54 of the N-th column are connected to each other, the fourth connection electrode 54 of the (N+1)-th column and the fourth connection electrode 54 of the (N+2)-th column are connected to each other, and the fourth connection electrode 54 of the (N+3)-th column and the fourth connection electrode 54 of the (N+4)-th column are connected to each other.

In an exemplary implementation mode, the fifth connection electrode 55 may be in a shape of bending line in which a main portion extends along the second direction Y, a first terminal of the fifth connection electrode 55 is connected to the second region of the fifth active layer through the eighth via V8, and a second terminal of the fifth connection electrode 55, after extending along the second direction Y, is connected to the second region of the eighth active layer through the twelfth via V12. In an exemplary implementation mode, since the second region of the fifth active layer serves as the first region of the third active layer and the second region of the fourth active layer at the same time, the fifth connection electrode 55 enables the first electrode of the third transistor T3, the second electrode of the fourth transistor T4, the second electrode of the fifth transistor T5 and the second electrode of the eighth transistor T8 to have a same potential to form a second node N2 of the pixel drive circuit.

In an exemplary implementation mode, the sixth connection electrode 56 may be in a shape of a block (such as a rectangle), and the sixth connection electrode 56 is connected to the second region of the sixth active layer (also the second region of the seventh active layer) through the ninth via V9. In an exemplary implementation mode, the sixth connection electrode 56 may serve as a second electrode of the sixth transistor T6 and a second electrode of the seventh transistor T7 simultaneously, and the sixth connection electrode 56 is configured to be connected with a twelfth connection electrode formed subsequently.

In an exemplary implementation mode, the seventh connection electrode 57 may be in a shape of a strip in which a main portion extends along the second direction Y, a first terminal of the seventh connection electrode 57 is connected to the first region of the first active layer through the first via V1, and a second terminal of the seventh connection electrode 57 is connected to the first initial connection block 41-1 through the fifteenth via V15. In an exemplary implementation mode, the seventh connection electrode 57 may serve as the first electrode of the first transistor T1, and since the first initial connection block 41-1 is connected to the first initial signal line 41, the seventh connection electrode 57 enables a first initial signal transmitted by the first initial signal line 41 to be written to the first electrode of the first transistor T1.

In an exemplary implementation mode, the eighth connection electrode 58 may be in a shape of a strip in which a main portion extends along the second direction Y, a first terminal of the eighth connection electrode 58 is connected to the first region of the seventh active layer through the tenth via V10, and a second terminal of the eighth connection electrode 58 is connected to the second initial connection block 42-1 through the sixteenth via V16. In an exemplary implementation mode, the eighth connection electrode 58 may serve as the first electrode of the seventh transistor T7, and since the second initial connection block 42-1 is connected to the second initial signal line 42, the eighth connection electrode 58 enables a second initial signal transmitted by the second initial signal line 42 to be written to the first electrode of the seventh transistor T7.

In an exemplary implementation mode, the ninth connection electrode 59 may be in a shape of a bending line in which a main portion extends along the second direction Y, a first end of the eighth connection electrode 58 is connected to a first region of the eighth active layer through the eleventh via V11, and a second end of the eighth connection electrode 58 is connected to the third initial connection block 43-1 through the seventeenth via V17. In an exemplary implementation mode, the ninth connection electrode 59 may serve as the first electrode of the eighth transistor T8, and since the third initial connection block 43-1 is connected to the third initial signal line 43, the ninth connection electrode 59 enables a third initial signal transmitted by the third initial signal line 43 to be written to the first electrode of the eighth transistor T8.

In an exemplary implementation mode, in one unit row, the ninth connection electrodes 59 in some of the two adjacent circuit units may be of an interconnected integral structure, so that the first electrodes of the eighth transistors T8 of adjacent circuit units may be ensured to be have a same potential, which is beneficial for improving uniformity of the display substrate, avoiding poor display of the display substrate and ensuring a display effect of the display substrate. For example, the ninth connection electrode 59 of the (N−1)-th column and the ninth connection electrode 59 of the N-th column are connected to each other, the ninth connection electrode 59 of the (N+1)-th column and the ninth connection electrode 59 of the (N+2)-th column are connected to each other, and the ninth connection electrode 59 of the (N+3)-th column and the ninth connection electrode 59 of the (N+4)-th column are connected to each other.

In an exemplary implementation mode, fourth conductive layers of adjacent unit columns may be mirror symmetrical with respect to a column dividing line. For example, the fourth conductive layer of the N-th column and the fourth conductive layer of the (N+1)-th column may be mirror symmetrical with respect to the column dividing line, the fourth conductive layer of the (N+1)-th column and the fourth conductive layer of the (N+2)-th column may be mirror symmetrical with respect to the column dividing line, and the fourth conductive layer of the (N+2)-th column and the fourth conductive layer of the (N+3)-th column may be mirror symmetrical with respect to the column dividing line. In an exemplary implementation mode, shapes of fourth conductive layers in a plurality of unit rows may be substantially the same.

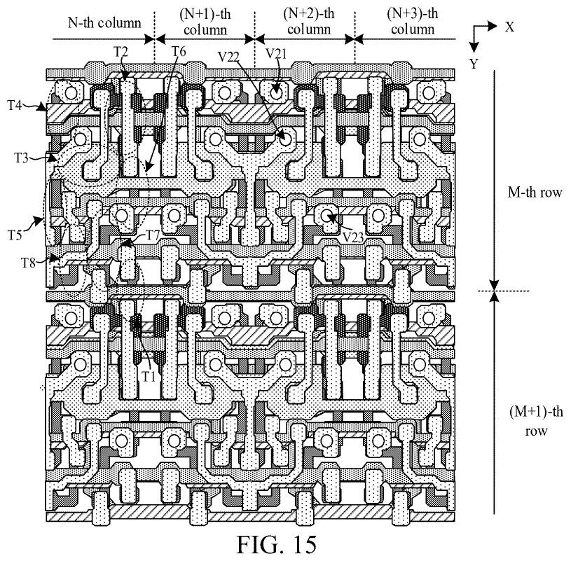

(9) A pattern of a first planarization layer is formed. In an exemplary implementation mode, forming the pattern of the first planarization layer may include: coating a first planarization thin film on the base substrate on which the aforementioned patterns are formed, patterning the first planarization thin film using a patterning process to form a first planarization layer covering the pattern of the fourth conductive layer, wherein the first planarization layer is provided with a plurality of vias, as shown in FIG. 15.

In an exemplary implementation mode, a plurality of vias in each circuit unit at least includes a twenty-first via V21, a twenty-second via V22, and a twenty-third via V23.

In an exemplary implementation mode, an orthographic projection of the twenty-first via V21 on the base substrate is located within a range of an orthographic projection of the third connection electrode 53 on the base substrate, the first planarization layer within the twenty-first via V21 is etched away to expose a surface of the third connection electrode 53, and the twenty-first via V21 is configured such that an eleventh connection electrode formed subsequently is connected with the third connection electrode 53 through the twenty-first via V21.

In an exemplary implementation mode, an orthographic projection of the twenty-second via V22 on the base substrate is within a range of an orthographic projection of the power supply connection block 54-1 of the fourth connection electrode 54 on the base substrate, the first planarization layer within the twenty-second via V22 is etched away to expose a surface of the power supply connection block 54-1, and the twenty-second via V22 is configured such that a power supply connection line formed subsequently is connected with the power supply connection block 54-1 through the twenty-second via V22.

In an exemplary implementation mode, an orthographic projection of the twenty-third via V23 on the base substrate is within a range of an orthographic projection of the sixth connection electrode 56 on the base substrate, the first planarization layer within the twenty-third via V23 is etched away to expose a surface of the sixth connection electrode 56, and the twenty-third via V23 is configured such that a twelfth connection electrode formed subsequently is connected with the sixth connection electrode 56 through the twenty-third via V23.

In an exemplary implementation mode, the plurality of vias on the first planarization layers of adjacent unit columns may be mirror symmetrical with respect to the column dividing line, and the shape of the plurality of vias on the first planarization layers in a plurality of unit rows may be substantially the same.

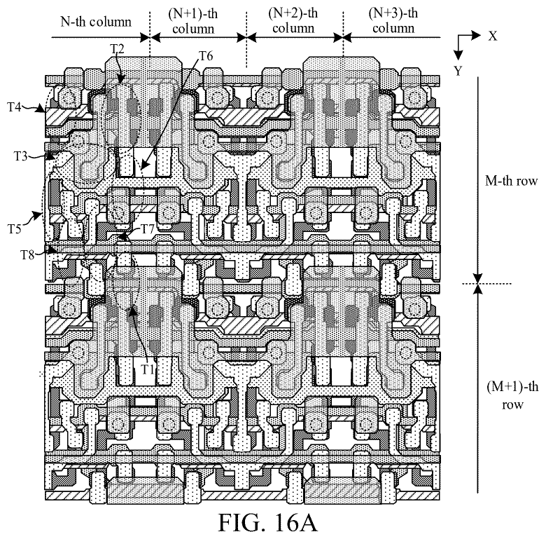

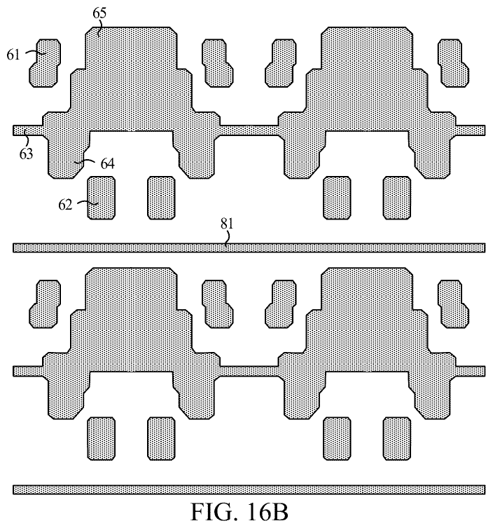

(10) A pattern of a fifth conductive layer is formed. In an exemplary implementation mode, forming the pattern of the fifth conductive layer may include: depositing a fifth conductive thin film on the base substrate on which the above-mentioned patterns are formed, and patterning the fifth conductive thin film using a patterning process to form the fifth conductive layer arranged on the first planarization layer, as shown in FIG. 16A and FIG. 16B. FIG. 16B is a schematic plan view of the fifth conductive layer in FIG. 16A. In an exemplary implementation mode, the fifth conductive layer may be referred to as a second source-drain metal (SD2) layer.

In an exemplary implementation mode, the fifth conductive layer of each circuit unit includes at least an eleventh connection electrode 61, a twelfth connection electrode 62, a power supply connection line 63, a first shielding electrode 64, and a second shielding electrode 65.

In an exemplary implementation mode, the eleventh connection electrode 61 may be in a shape of a strip in which a main portion extends along the second direction Y, the eleventh connection electrode 61 is connected to the third connection electrode 53 through the twenty-first via V21, and the eleventh connection electrode 61 is configured to be connected to a data signal line formed subsequently.

In an exemplary implementation mode, the twelfth connection electrode 62 may be in a shape of a strip in which a main portion extends along the second direction Y, the twelfth connection electrode 62 is connected to the sixth connection electrode 56 through the twenty-third via V23, and the twelfth connection electrode 62 is configured to be connected to an anode connection electrode formed subsequently.

In an exemplary implementation mode, the power supply connection line 63 may be in a shape of a line in which a main portion extends along the first direction X, and the power supply connection line 63 is connected to the power supply connection block 54-1 of each circuit unit through the twenty-second via V22. Since the power supply connection line 63 is configured to be connected with a subsequently formed first power supply line, it can be reused as a transverse power supply signal line, the power supply connection line 63 is connected with the fourth connection electrode 54 of each circuit unit, and the fourth connection electrode 54 is respectively connected with the first region of the fifth active layer and the second plate 32 of the storage capacitor, and the power supply connection line 63 can realize writing the first power supply signal to all the fifth transistors T5 and the second plates 32 of the storage capacitors in one unit row, so that the second plates of a plurality of storage capacitors in one unit row may be ensured to be have a same potential, which is beneficial for improving uniformity of the display substrate, avoiding poor display of the display substrate and ensuring a display effect of the display substrate.

In an exemplary implementation mode, the first shielding electrode 64 and the second shielding electrode 65 may be in a shape of a block (such as a rectangle) and connected to the power supply connection line 63. In an exemplary implementation mode, the first shielding electrode 64 may be located at a side of the power supply connection line 63 in the second direction Y, the second shielding electrode 65 may be located at a side of the power supply connection line 63 in an opposite direction of the second direction Y, and orthographic projections of the power supply connection line 63, the first shielding electrode 64, and the second shielding electrode 65 on the base substrate are at least partially overlapped with an orthographic projection of the first connection electrode 51 on the base substrate. Since the power supply connection line 63 is connected with a first power supply line formed subsequently, the power supply connection line 63, the first shielding electrode 64 and the second shielding electrode 65 with a constant potential can not only effectively shield the influence of data voltage jump and other signals on the first node N1 in the pixel drive circuit, but also avoid the influence of the data voltage jump and other signals on the potential of the first node N1, and improve the driving performance of the pixel drive circuit.

In an exemplary implementation mode, orthographic projections of the power supply connection line 63 and the second shielding electrode 65 on the base substrate at least partially overlap an orthographic projection of the second active layer on the base substrate, so that the power supply connection line 63 and the second shielding electrode 65 may shield the second active layer, may block light emitted by a light emitting structure layer and light reflected by a film layer from irradiating the second transistor of oxide T2, may prevent the oxide transistor from characteristic drift due to illumination, thus improving electrical characteristics of the oxide transistor.

In an exemplary implementation mode, in one unit row, the second shielding electrodes 65 in some of two adjacent circuit units may be of an interconnected integral structure, and the shielding effect of shielding the second transistor T2 may be improved.

In an exemplary implementation mode, the fifth conductive layer may further include a first connection line 81. The first connection line 81 may be in a shape of a line in which a main portion extends along the first direction X, and the first connection line 81 is configured as a transverse trace in the data connection lines.

In an exemplary implementation mode, an orthographic projection of the first connection line 81 on the base substrate is at least partially overlapped with an orthographic projection of the first initial signal line 41 on the base substrate, so that the first initial signal line 41 with a constant potential can effectively shield the influence of the voltage jump in the first connection line 81 on the pixel drive circuit.

In an exemplary implementation mode, the fifth conductive layers of adjacent unit columns may be mirror symmetrical with respect to a column dividing line. For example, the fifth conductive layer of the N-th column and the fifth conductive layer of the (N+1)-th column may be mirror symmetrical with respect to the column dividing line, the fifth conductive layer of the (N+1)-th column and the fifth conductive layer of the (N+2)-th column may be mirror symmetrical with respect to the column dividing line, and the fifth conductive layer of the (N+2)-th column and the fifth conductive layer of the (N+3)-th column may be mirror symmetrical with respect to the column dividing line. In an exemplary implementation mode, shapes of fifth conductive layers in a plurality of unit rows may be substantially the same.

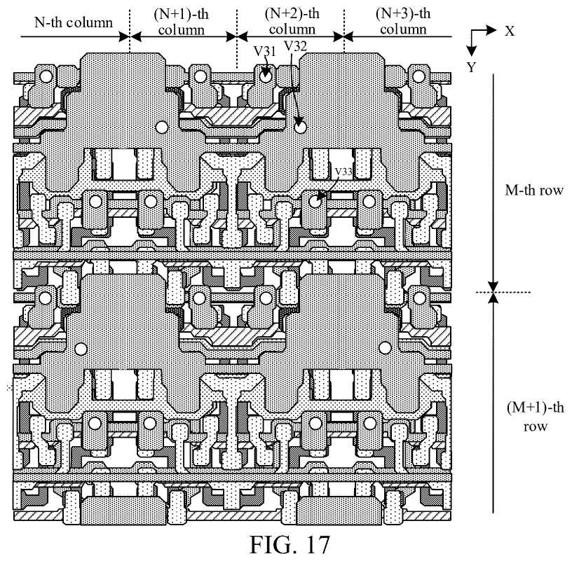

(11) A pattern of a second planarization layer is formed. In an exemplary implementation mode, forming the pattern of the second planarization layer may include coating a second planarization thin film on the base substrate on which the aforementioned patterns are formed, patterning the second planarization thin film using a patterning process to form the second planarization layer covering the pattern of the fifth conductive layer, a plurality of vias are provided on the second planarization layer, as shown in FIG. 17.

In an exemplary implementation mode, a plurality of vias in each circuit unit at least includes a thirty-first via V31, a thirty-second via V32, and a thirty-third via V33.

In an exemplary implementation mode, an orthographic projection of the thirty-first via V31 on the base substrate is within a range of an orthographic projection of the eleventh connection electrode 61 on the base substrate, the second planarization layer within the thirty-first via V31 is etched away to expose a surface of the eleventh connection electrode 61, and the thirty-first via V31 is configured such that a data signal line formed subsequently is connected with the eleventh connection electrode 61 through the thirty-first via V31.

In an exemplary implementation mode, an orthographic projection of the thirty-second via V32 on the base substrate is within a range of an orthographic projection of the power supply connection line 63 on the base substrate, the second planarization layer in the thirty-second via V32 is etched away to expose a surface of the power supply connection line 63, and the thirty-second via V32 is configured such that a first power supply line formed subsequently is connected with the power supply connection line 63 through the thirty-second via V32.

In an exemplary implementation mode, an orthographic projection of the thirty-third via V33 on the base substrate is within a range of an orthographic projection of the twelfth connection electrode 62 on the base substrate, the second planarization layer within the thirty-third via V33 is etched away to expose a surface of the twelfth connection electrode 62, and the thirty-third via V33 is configured such that an anode connection electrode formed subsequently is connected with the twelfth connection electrode 62 through the thirty-third via V33.

In an exemplary implementation mode, a plurality of vias on the second planarization layers of adjacent unit columns may be mirror symmetrical with respect to a column dividing line, and the shapes of the plurality of vias on the second planarization layers in a plurality of unit rows may be substantially the same.

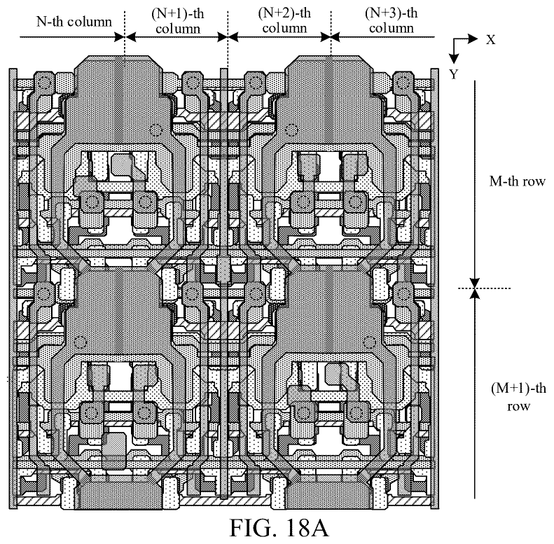

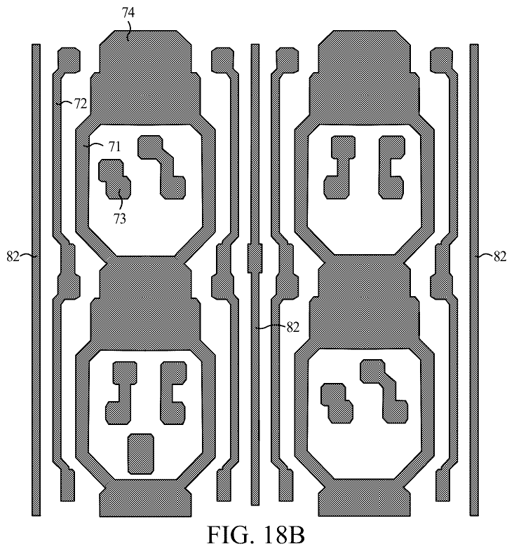

(12) A pattern of a sixth conductive layer is formed. In an exemplary implementation mode, forming a sixth conductive layer may include: depositing a sixth conductive thin film on the base substrate on which the aforementioned patterns are formed, patterning the sixth conductive thin film using a patterning process to form a sixth conductive layer disposed on the second planarization layer, as shown in FIG. 18A and FIG. 18B, and FIG. 18B is a schematic plan view of the sixth conductive layer in FIG. 18A. In an exemplary implementation mode, the sixth conductive layer may be referred to as a third source-drain metal (SD3) layer.

In an exemplary implementation mode, a sixth conductive layer of each circuit unit includes at least a first power supply line 71, a data signal line 72 and an anode connection electrode 73.

In an exemplary implementation mode, the first power supply line 71 may in a shape of a bending line in which a main portion extends along the second direction Y, and the first power supply line 71 is connected to the power supply connection line 63 through the thirty-second via V32. Since the power supply connection line 63 is connected with the fourth connection electrode 54, and the fourth connection electrode 54 is connected with the first region of the fifth active layer and the second plate 32 of the storage capacitor respectively, it is achieved that the first power supply line 71 writes a first power supply signal to the fifth transistor T5 and the second plate 32 of the storage capacitor.

In an exemplary implementation mode, the first power supply line 71 may be of a bending line with unequal widths, which may not only facilitate a layout of a pixel structure, but also reduce a parasitic capacitance between the first power supply line and a data signal line.

In an exemplary implementation mode, the first power supply line 71 may be connected with an anode pad 74, the anode pad 74 may be disposed on a side of the first power supply line 71 in the first direction X or on a side in an opposite direction of the first direction X. An orthographic projection of the anode pad 74 on the base substrate is at least partially overlapped with an orthographic projection of the second shielding electrode 65 on the base substrate, and the anode pad 74 is configured as a planarization layer for raising the anode.

In an exemplary implementation mode, in one unit row, the pads 74 in some of two adjacent circuit units may be of an interconnected integral structure. For example, the pad 74 of the N-th column and the pad 74 of the (N+1)-th column are connected to each other so that the first power supply lines 71 in two circuit units are connected to each other. As another example, the pad 74 of the (N+2)-th column and the pad 74 of the (N+3)-th column are connected to each other so that the first power supply lines 71 in two circuit units are connected to each other.

In an exemplary implementation mode, the first power supply line 71 is connected to the power supply connection line 63, it is achieved that the power supply connection line 63 in which a main body portion extends along the first direction X and the first power supply line 71 in which a main body portion extends along the second direction Y are connected with each other, so that the first power supply line 71 and the power supply connection line 63 form a grid connecting structure for transmitting the first power supply signal on the display substrate, which may not only effectively reduce the first power supply line and reduce a voltage drop of the first power supply signal, but also effectively improve uniformity of the first power supply signal in the display substrate, effectively improve uniformity of display, and improve display quality.

In an exemplary implementation mode, the data signal line 72 may have a shape of a line with a main body portion extending along the second direction Y, and the data signal line 72 is connected with the eleventh connection electrode 61 through the thirty-first via V31. Since the eleventh connection electrode 61 is connected with the third connection electrode 53 through a via and the third connection electrode 53 is connected with the first region of the fourth active layer through a via, a connection between the data signal line 72 and the first electrode of the fourth transistor T4 is achieved, and the data signal line 72 may write a data signal into the first electrode of the fourth transistor T4.

In an exemplary implementation mode, since the data signal line is disposed in the third source-drain metal (SD3) layer and the first planarization layer and the second planarization layer which are relatively thick are spaced between the data signal line and a corresponding signal line, a distance between the data signal line and the corresponding signal line is increased, and a parasitic capacitance between the data signal line and the corresponding signal line is reduced, thereby effectively reducing a capacitive load of the data signal line.

In an exemplary implementation mode, the anode connection electrode 73 may be in a shape of a block (e.g., a rectangle), the anode connection electrode 73 is connected to the twelfth connection electrode 62 through the thirty-third via V33, and the anode connection electrode 73 is configured to be connected to an anode formed subsequently. Since the twelfth connection electrode 62 is connected with the sixth connection electrode 56 through a via, and the sixth connection electrode 56 is connected with the second region of the sixth active layer and the second region of the seventh active layer through a via, a connection between the anode formed subsequently, and the second electrode of the sixth transistor T6 and the second electrode of the seventh transistor T7 may be achieved, and the pixel drive circuit may drive a light emitting device to emit light.

In an exemplary implementation mode, the sixth conductive layer may further include a second connection line 82. The second connection line 82 may have a shape of a line with a main body portion extending along the second direction Y, and may be located in a gap between the pixel drive circuits of some adjacent unit columns. For example, the second connection line 82 may be located between the pixel drive circuit of the (N−1)-th column and the pixel drive circuit of the N-th column. As another example, the second connection line 82 may be located between the pixel drive circuit of the (N+1)-th column and the pixel drive circuit of the (N+2)-th column. For another example, the second connection line 82 may be located between the pixel drive circuit of the (N+3)-th column and the pixel drive circuit of the (N+4)-th column.

In an exemplary implementation mode, at least one second connection line 82 may be disposed between two data signal lines 72 of adjacent unit columns and the two data signal lines 72 located at two sides of the second connection line 82 may be mirror symmetrical with respect to the second connection line 82.

In an exemplary implementation mode, one second connection line 82 and two data signal lines 72 may be disposed between two first power supply lines 71 of adjacent unit columns, and the two first power supply lines 71 may be mirror symmetrical with respect to the second connection lines 82.

In an exemplary implementation mode, in at least one circuit unit, the second connection line 82 may be connected to the first connection line 81 through a via, and in at least another circuit unit, the data signal line 72 may be connected to the first connection line 81 through a via, thus realizing the sequential connection of the second connection line 82, the first connection line 81, and the data signal line 72, and the data signal of the bonding region may be transmitted to the data signal line 72 through the second connection line 82 and the first connection line 81.

In an exemplary implementation mode, since the second connection line is disposed in the third source-drain metal (SD3) layer, and the first planarization layer and the second planarization layer which are relatively thick are spaced between the second connection line and a corresponding signal line, a distance between the second connection line and the corresponding signal line is increased, and a parasitic capacitance between the second connection line and the corresponding signal line is reduced, thereby effectively reducing a capacitance load of the second connection line.

In an exemplary implementation mode, since the first connection line is disposed in the second source-drain metal (SD2) layer and the second connection line is disposed in the third source-drain metal (SD3) layer, the first connection line and the second connection line may be connected with only one planarization layer via, thereby minimizing occupied space and facilitating achievement of high-resolution display.

In an exemplary implementation mode, the first power supply lines 71 and the data signal lines 72 of adjacent unit columns may be mirror symmetrical with respect to the column dividing line. For example, the first power supply lines 71 and the data signal lines 72 of the N-th and (N+1)-th columns may be mirror symmetrical with respect to the column dividing line, and the first power supply lines 71 and the data signal lines 72 of the (N+1)-th and (N+2)-th columns may be mirror symmetrical with respect to the column dividing line. The first power supply lines 71 and the data signal lines 72 of the (N+2)-th column and the (N+3)-th column may be mirror symmetrical with respect to the column dividing line. In an exemplary implementation mode, the shapes of the first power supply lines 71 and the data signal lines 72 in a plurality of unit rows may be substantially the same.

In an exemplary implementation mode, the position and shape of the anode connection electrode 73 in a M-th row and an N-th column may be substantially the same as the position and shape of the anode connection electrode 73 in a (M+1)-th row and an (N+2)-th column, the position and shape of the anode connection electrode 73 in the M-th row and an (N+1)-th column may be substantially the same the position and shape of the anode connection electrode 73 in the (M+1)-th row and an (N+3)-th column, the position and shape of the anode connection electrode 73 in the M-th row and the (N+2)-th column may be substantially the same as the position and shape of the anode connection electrode 73 in the (M+1)-th row and the N-th column, and the position and shape of the anode connection electrode 73 in the M-th row and the (N+3)-th column may be substantially the same as the position and shape of the anode connection electrode 73 in the (M+1)-th row and the (N+1)-th column.

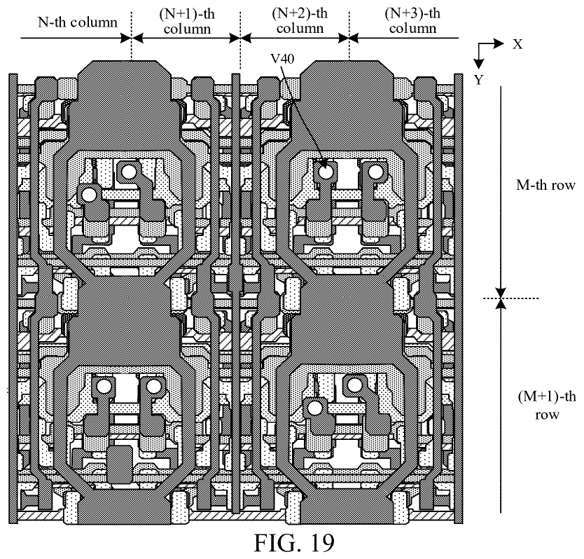

(13) A pattern of a third planarization layer is formed. In an exemplary implementation mode, forming the pattern of the third planarization layer may include: coating a third planarization thin film on the base substrate on which the aforementioned patterns are formed, patterning the third planarization thin film using a patterning process, forming a third planarization layer covering the pattern of the sixth conductive layer, and a plurality of anode vias V40 are provided on the third planarization layer, as shown in FIG. 19.

In an exemplary implementation mode, an orthographic projection of the anode via V40 of each circuit unit on the base substrate is within a range of an orthographic projection of the anode connection electrode 73 on the base substrate, the third planarization layer within the anode via V40 is removed to expose a surface of the anode connection electrode 73, and the anode via V40 is configured such that an anode formed subsequently is connected with the anode connection electrode 73 through the anode via V40.

So far, a drive circuit layer has been prepared on the base substrate. In a plane parallel to the display substrate, the drive circuit layer may include a plurality of circuit units, each of which may include a pixel drive circuit, and a first scan signal line, a second scan signal line, a third scan signal line, a fourth scan signal line, a light emitting signal line, a data signal line, a first power supply line, a first initial signal line, a second initial signal line, and a third initial signal line connected to the pixel drive circuit. In a plane perpendicular to the display substrate, the drive circuit layer may include a shield layer, a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, a second planarization layer, a sixth conductive layer, and a third planarization layer disposed sequentially on the base substrate. The shield layer may include at least a shield electrode, the first semiconductor layer may include at least active layers of the first transistor, the third transistor to the seventh transistor, the first conductive layer may include at least a first scan signal line, a second scan signal line, a third scan signal line, a light emitting signal line, and a first plate of the storage capacitor, the second conductive layer may include at least a shield line and a second plate of the storage capacitor, the second semiconductor layer may include at least an active layer of the second transistor, the third conductive layer may include at least a first initial signal line, a second initial signal line, a third initial signal line, and a fourth scan signal line, the fourth conductive layer may include at least a plurality of connection electrodes, the fifth conductive layer may include at least a power supply connection line and a first connection line, and the sixth conductive layer may include at least a first power supply line, a data signal line, an anode connection electrode, and a second connection line.

In an exemplary implementation mode, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation mode, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, multiple layers, or a composite layer. The first planarization layer, the second planarization layer, and the third planarization layer may be made of an organic material, such as a resin.

In an exemplary implementation mode, in one unit row, pixel drive circuits in two adjacent circuit units may be substantially mirror symmetrical with respect to a column dividing line, which is a straight line located between two adjacent circuit units and extending along the second direction Y. For example, the pixel drive circuit of the N-th column and the pixel drive circuit of the (N+1)-th column may be mirror symmetrical with respect to the column dividing line. As another example, the pixel drive circuit of the (N+1)-th column and the pixel drive circuit of the (N+2)-th column may be mirror symmetrical with respect to the column dividing line.

In an exemplary implementation mode, the case where the pixel drive circuits in two adjacent circuit units may be substantially mirror symmetrical with respect to a column dividing line may include any one or more of the following: the first semiconductor layers in two adjacent circuit units in a unit row may be mirror symmetrical with respect to a column dividing line, the first conductive layers in two adjacent circuit units in a unit row may be mirror symmetrical with respect to the column dividing line, the second conductive layers in two adjacent circuit units in a unit row may be mirror symmetrical with respect to the column dividing line, the second semiconductor layers in two adjacent circuit units in a unit row may be mirror symmetrical with respect to the column dividing line, the third conductive layers in two adjacent circuit units in a unit row may be mirror symmetrical with respect to the column dividing line, the fourth conductive layers in two adjacent circuit units in a unit row may be mirror symmetrical with respect to the column dividing line, the fifth conductive layers in two adjacent circuit units in a unit row may be mirror symmetrical with respect to the column dividing line, and the sixth conductive layers (except for the anode connection electrodes) in two adjacent circuit units in a unit row may be mirror symmetrical with respect to the column dividing line.

In an exemplary implementation mode, after preparation of the drive circuit layer is completed, a light emitting structure layer is prepared on the drive circuit layer, and a preparation process of the light emitting structure layer may include following operations.

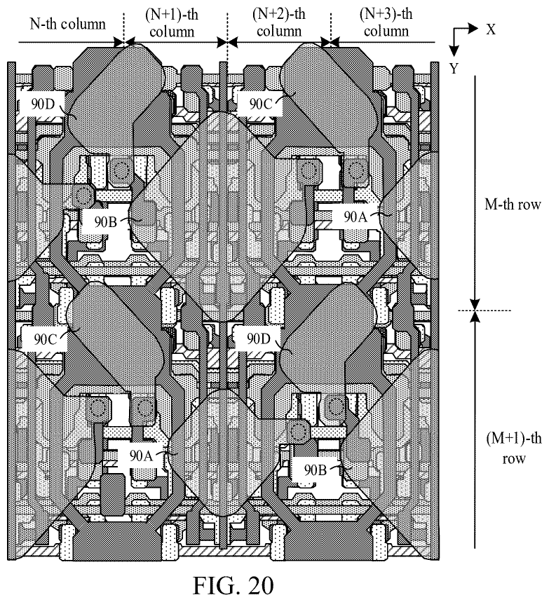

(14) A pattern of an anode conductive layer is formed. In an exemplary implementation mode, forming a pattern of an anode conductive layer may include: depositing an anode conductive thin film on the base substrate on which the above-mentioned patterns are formed, patterning the anode conductive thin film using a patterning process to form an anode conductive layer disposed on the third planarization layer, wherein the anode conductive layer at least includes a plurality of patterns of anodes, as shown in FIG. 20.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the plurality of patterns of anodes may include a first anode 90A located in a red light emitting unit emitting red light, a second anode 90B located in a blue light emitting unit emitting blue light, a third anode 90C located in a first green light emitting unit emitting green light, and a fourth anode 90D located in a second green light emitting unit emitting green light.

In an exemplary implementation mode, the first anode 90A, the second anode 90B, the third anode 90C, and the fourth anode 90D may be respectively connected with the anode connection electrode 73 of a circuit unit where they are located through the anode via V40.

In an exemplary implementation mode, at least one of the first anode 90A, the second anode 90B, the third anode 90C, and the fourth anode 90D may include an anode main body portion and an anode connection portion connected to each other, the anode main body portion may have a rhombus shape, a corner portion of the rectangular shape may be provided with an arc-shaped chamfer, the anode connection portion may be in a shape of a strip, a first end of the anode connection portion is connected to the anode main body portion, and a second end of the anode connection portion, after extending in a direction away from the anode main body portion, is connected to the anode connection electrode 73 through the anode via V40.

In an exemplary implementation mode, orthographic projections of the first anode 90A and the second anode 90B on the base substrate at least partially overlap with orthographic projections of the power supply connection line 63, the first connection line 81, the first power supply line 71, the data signal line 72, and the second connection line 82 on the base substrate.

In an exemplary implementation mode, orthographic projections of the third anode 90C and the fourth anode 90D on the base substrate at least partially overlap with an orthographic projection of the anode pad 74 on the base substrate.

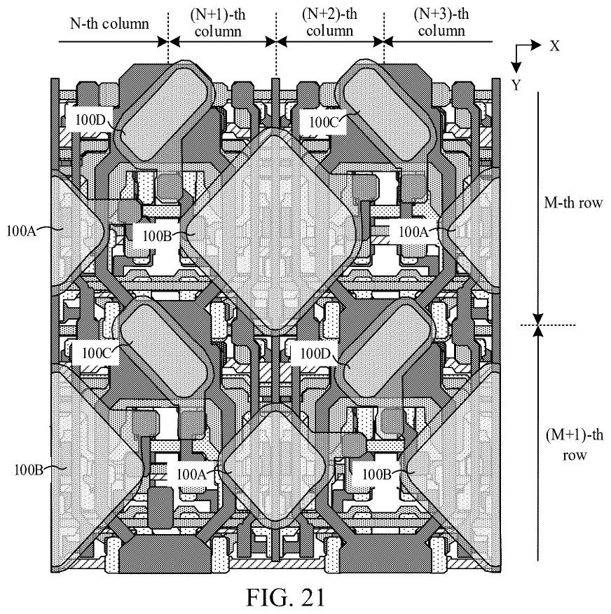

(15) A pattern of a pixel definition layer is formed. In an exemplary implementation mode, forming the pattern of the pixel definition layer may include: coating a pixel definition thin film on the base substrate on which the above-mentioned patterns, patterning the pixel definition thin film using a patterning process, to form the pattern of the pixel definition layer covering the pattern of the anode conductive layer, and a plurality of pixel openings are provided on the pixel definition layer, as shown in FIG. 21.

In an exemplary implementation mode, the plurality of pixel openings may include a first pixel opening 100A located in a red light emitting unit emitting red light, a second pixel opening 100B located in a blue light emitting unit emitting blue light, a third pixel opening 100C located in a first green light emitting unit emitting green light, and a fourth pixel opening 100D located in a second green light emitting unit emitting green light, wherein the pixel definition thin films in the first pixel opening 100A, the second pixel opening 100B, the third pixel opening 100C and the fourth pixel opening 100D are removed to expose surfaces of the first anode 90A, the second anode 90B, the third anode 90C, and the fourth anode 90D, respectively.

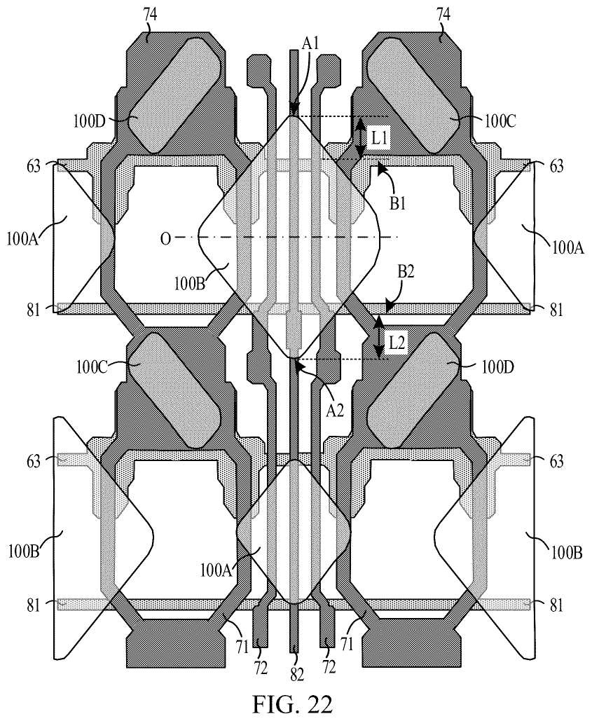

FIG. 22 is a schematic diagram of a positional relationship between pixel openings and a signal line according to the present disclosure. As shown in FIG. 22, in an exemplary implementation mode, orthographic projections of the first pixel opening 100A, the second pixel opening 100B, the third pixel opening 100C, and the fourth pixel opening 100D on the base substrate at least partially overlaps an orthographic projection of at least one signal line on the base substrate.

In an exemplary implementation mode, orthographic projections of the first pixel opening 100A and the second pixel opening 100B on the base substrate at least partially overlap with orthographic projections of a plurality of signal lines extending along the second direction Y on the base substrate. In an exemplary implementation mode, the plurality of signal lines may include two first power supply lines 71, two data signal lines 72, and one second connection line 82, the two data signal lines 72 may be respectively located at two sides of the second connection line 82 in the first direction X, and the two first power supply lines 71 may be respectively located at two sides of the two data signal lines 72 in the first direction X.

In an exemplary implementation mode, an orthographic projection of the second connection line 82 on the base substrate is at least partially overlapped with orthographic projections of a geometric center of the first pixel opening 100A and a geometric center of the second pixel opening 100B on the base substrate. Since the two data signal lines 72 located at two sides of the second connection line 82 are mirror symmetrical with respect to the second connection line 82, and the two first power supply lines 71 located at a side of the data signal line 72 away from the second connection line 82 are mirror symmetrical with respect to the second connection line 82, in the first direction X, the first anode 90A exposed by the first pixel opening 100A and the second anode 90B exposed by the second pixel opening 100B are ensured to have not only good flatness but also good flatness symmetry, which can effectively improve color deviation and improve display quality.

In an exemplary implementation mode, orthographic projections of the first pixel opening 100A and the second pixel opening 100B on the base substrate at least partially overlap with orthographic projections of at least two signal lines extending along the first direction X on the base substrate. In an exemplary implementation mode, the at least two signal lines may include the power supply connection line 63 and the first connection line 81. For the first pixel opening 100A, the power supply connection line 63 and the first connection line 81 may be located at two sides of a geometric center of the first pixel opening 100A in the second direction Y, respectively. For the second pixel opening 100B, the power supply connection line 63 and the first connection line 81 may be located at two sides of a geometric center of the second pixel opening 100B in the second direction Y, respectively.

In an exemplary implementation mode, the power supply connection line 63 and the first connection line 81 may be disposed symmetrically with respect to a center line of a pixel opening. For example, for the first pixel opening 100A, the power supply connection line 63 and the first connection line 81 may be disposed symmetrically with respect to a center line of the first pixel opening 100A, which is a straight line extending along the first direction X and passing through the geometric center of the first pixel opening 100A. As another example, for the second pixel opening 100B, the power supply connection line 63 and the first connection line 81 may be disposed symmetrically with respect to a center line of the second pixel opening 100B, which is a straight line extending along the first direction X and passing through the geometric center of the second pixel opening 100B.

In an exemplary implementation mode, for at least one pixel opening of the first pixel opening 100A and the second pixel opening 100B, a distance between the power supply connection line 63 and one end of the pixel opening may be substantially the same as a distance between the first connection line 81 and the other end of the pixel opening.

In an exemplary implementation mode, taking the second pixel opening 100B as an example, the second pixel opening 100B has a center line O, a first end A1 located at a side of the power supply connection line 63 away from the center line O, and a second end A2 located at a side of the first connection line 81 away from the center line O, the power supply connection line 63 has a first edge B1 on a side away from the center line O, the first connection line 81 has a second edge B2 on a side away from the center line O, there is a first distance L1 between the first end A1 and the first edge B1, there is a second distance L2 between the second end A2 and the second edge B2, and the ratio of the first distance L1 to the second distance L2 may be about 0.9 to 1.1.

In an exemplary implementation mode, the ratio of the first distance L1 to the second distance L2 may be about 1.0, and thus, in the second direction Y, it is ensured that the first anode 90A exposed by the first pixel opening 100A and the second anode 90B exposed by the second pixel opening 100B not only have good flatness but also have good flatness symmetry, which can effectively improve color deviation and improve display quality.

In an exemplary implementation mode, orthographic projections of the third pixel opening 100C and the fourth pixel opening 100D on the base substrate at least partially overlap with an orthographic projection of the anode pad 74 on the base substrate, the orthographic projections of the third pixel opening 100C and the fourth pixel opening 100D on the base substrate do not overlap with orthographic projections of the power supply connection line 63 and the first connection line 81 extending along the first direction X on the base substrate, and the orthographic projections of the third pixel opening 100C and the fourth pixel opening 100D on the base substrate do not overlap with orthographic projections of the first power supply line 71, the data signal line 72, and the second connection line 82 extending along the second direction Y on the base substrate.

In an exemplary implementation mode, the orthographic projections of the third pixel opening 100C and the fourth pixel opening 100D on the base substrate may be located within a range of orthographic projections of the anode pads 74 in corresponding circuit units on the base substrate, respectively. Since the anode pad 74 is disposed on a side of the second planarization layer away from the base substrate and has good flatness, both the third anode 90C exposed by the third pixel opening 100C and the fourth anode 90D exposed by the fourth pixel opening 100D have good flatness, which can effectively improve color deviation and improve display quality.

In an exemplary implementation mode, a subsequent preparation process may include: forming an organic light emitting layer using an evaporation process and inkjet printing process at first, then forming a cathode on the organic light emitting layer, and then forming an encapsulation structure layer, wherein the encapsulation structure layer may include a first encapsulation layer, a second encapsulation layer and a third encapsulation layer which are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting device.

Through research, it is found that the main cause of problems such as color shift in existing display apparatuses is due to poor anode flatness. In the display substrate according to an exemplary embodiment of the present disclosure, the first connection line and the power supply connection line extending along the first direction (transverse) are provided in the second source-drain metal layer, and the second connection line, the data signal line and the first power supply line extending along the second direction (longitudinal) are provided in the third source-drain metal layer, such that a plurality of transverse metal lines and a plurality of longitudinal metal lines under the anode are substantially mirror symmetrical with respect to a center line, and thus an anode exposed by a pixel opening has not only good flatness but also good flat symmetry, which can effectively improve the color deviation and improve the display quality.

Comparative tests indicate that for an existing structure in which a first pixel opening and a second pixel opening overlap with a transverse signal line, a flatness of an anode exposed by the first pixel opening is about 0.12, and a flatness of an anode exposed by the second pixel opening is about 0.36. For the presently disclosed structure in which the first pixel opening and the second pixel opening overlap the power supply connection line and the first power supply line, the flatness of the anode exposed by the first pixel opening is about 0.05, and the flatness of the anode exposed by the second pixel opening is about 0.10. Therefore, the structure of the display substrate according to the present disclosure allows the anode to have good flatness, and effectively improves color deviation.

In the present disclosure, a power supply connection line extending along the first direction is provided on the second source-drain metal layer, a first power supply line extending along the second direction is provided on the third source-drain metal layer, and the first power supply line is connected with the power supply connection line, so that the first power supply line and the power supply connection line form a mesh-like mesh structure for transmitting the first power supply signal on the display substrate, which can effectively reduce the resistance of the power supply line and reduce the voltage drop of the first power supply signal, which can be reduced by about 22% in the case of a brightness of 500 nits, and but also can effectively improve the uniformity of the first power supply signal in the display substrate, effectively improve the display uniformity, which can be improved by about 3%, and improve the display effect and the display quality.

In the present disclosure, by disposing the first connection line in the second source-drain metal layer and the second connection line in the third source-drain metal layer, the first connection line and the second connection line may be connected with only one planarization layer via, thereby minimizing occupied space, facilitating achievement of high-resolution display, and a resolution (PPI) of an LTPO display substrate may be effectively increased while achieving a narrow bezel. In the present disclosure, by disposing the data signal line and the second connection line in the third source-drain metal layer, a distance between the data signal line and the second connection line, and the corresponding signal line is increased, and a parasitic capacitance between the data signal line and the second connection line, and the corresponding signal line is reduced, thereby effectively reducing a capacitance load of the data signal line and the second connection line. In the present disclosure, by providing a shielding electrode in the second source-drain metal layer, on the one hand, the shielding electrode can may block light emitted by a light emitting device and light reflected by a film layer from irradiating an oxide transistor, may prevent the oxide transistor from characteristic drift due to illumination, thus improving electrical characteristics of the oxide transistor; on the other hand, the shielding electrode can effectively shield an influence of data voltage jump and other signals on the first node in the pixel drive circuit, avoid an influence of the data voltage jump and other signals on a potential of the first node, effectively avoid deterioration of cross talk. The preparation process in the present disclosure may be compatible well with an existing preparation process, is simple in process implementation, is easy to implement, and has a high production efficiency, a low production cost, and a high yield.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure.

In an exemplary implementation mode, the display substrate of the present disclosure may be applied to another display apparatus having a pixel drive circuit, such as quantum dot display, which is not limited in the present disclosure.

The present disclosure also provides a preparation method for a display substrate, for preparing the display substrate according to the foregoing embodiments. In an exemplary implementation mode, the preparation method may include:

Forming a drive structure layer on a base substrate, wherein the drive structure layer includes a plurality of circuit units and at least two signal lines extending along a first direction, at least one circuit unit includes a pixel drive circuit;

Forming a light emitting structure layer on the drive structure layer, wherein the light emitting structure layer includes a plurality of light emitting units, at least one light emitting unit includes an anode and a pixel definition layer disposed on a side of the anode away from the base substrate, the anode is connected to a pixel drive circuit of a corresponding circuit unit, the pixel definition layer is provided with a pixel opening exposing the anode;

The drive structure layer further includes at least two signal lines extending along a first direction, in at least one pixel opening, an orthographic projection of the pixel opening on the base substrate is at least partially overlapped with an orthographic projection of the at least two signal lines on the base substrate, and the at least two signal lines are respectively located at two sides of a geometric center of the pixel opening in a second direction, and the first direction and the second direction intersect.

Although implementation modes disclosed in the present disclosure are as above, it should be noted that the above implementation modes are exemplary only rather than restrictive. Therefore, the present disclosure is not limited to what is specifically shown and described herein. Various modifications, substitutions or omissions may be made in forms and details of implementation modes without departing from the scope of the present disclosure.

1. A display substrate comprising a drive structure layer disposed on a base substrate and a light emitting structure layer disposed on a side of the drive structure layer away from the base substrate; wherein
the drive structure layer comprises a plurality of circuit units, and at least one circuit unit comprises a pixel drive circuit;
the light emitting structure layer comprises a plurality of light emitting units, at least one light emitting unit comprises an anode and a pixel definition layer disposed on a side of the anode away from the base substrate, the anode is connected to a pixel drive circuit of a corresponding circuit unit, and the pixel definition layer is provided with a pixel opening exposing the anode; and
the drive structure layer further comprises at least two signal lines extending along a first direction, in at least one pixel opening, an orthographic projection of the pixel opening on the base substrate is at least partially overlapped with orthographic projections of the at least two signal lines on the base substrate, and the at least two signal lines are respectively located at two sides of a geometric center of the pixel opening in a second direction, and the first direction and the second direction intersect.

2. The display substrate according to claim 1, wherein
the at least two signal lines comprise a first connection line and a power supply connection line, the power supply connection line is connected to a data signal line extending along the second direction, the power supply connection line is connected to a first power supply line extending along the second direction, and the data signal line and the first power supply line are connected to the pixel drive circuits; and
in the at least one pixel opening, the first connection line and the power supply connection line are disposed symmetrically with respect to a center line, and the center line is a straight line extending along the first direction and passing through the geometric center of the pixel opening.

3. The display substrate according to claim 2, wherein
in the at least one pixel opening, the pixel opening comprises a first end at a side of the power supply connection line away from the center line and a second end at a side of the first connection line away from the center line,
the power supply connection line comprises a first edge on a side away from the center line,
the first connection line comprises a second edge on a side away from the center line, the first end has a first distance from the first edge,
the second end has a second distance from the second edge, and
a ratio of the first distance to the second distance is 0.9 to 1.1.

4. The display substrate according to claim 2, wherein
the drive structure layer further comprises a second connection line extending along the second direction,
the second connection line is connected to the first connection line, and
in the at least one pixel opening, an orthographic projection of the second connection line on the base substrate is at least partially overlapped with an orthographic projection of the geometric center of the pixel opening on the base substrate.

5. The display substrate according to claim 4, wherein
the orthographic projection of the pixel opening on the base substrate at least partially overlaps orthographic projections of two data signal lines on the base substrate,
the second connection line is disposed between the two data signal lines, and
the two data signal lines are disposed symmetrically with respect to the second connection line

6. The display substrate according to claim 5, wherein
the orthographic projection of the pixel opening on the base substrate is at least partially overlapped with orthographic projections of two first power supply lines on the base substrate,
the second connection line and the two data signal lines are disposed between the two first power supply lines, and
the two first power supply lines are disposed symmetrically with respect to the second connection line.

7. The display substrate according to claim 1, wherein
the drive structure layer further comprises a plurality of power supply connection lines extending along the first direction and a plurality of first power supply lines extending along the second direction, and
the power supply connection lines and the first power supply lines are connected to form a grid connecting structure for transmitting a first power supply signal.

8. The display substrate according to claim 7, wherein
on a plane perpendicular to the display substrate, the drive structure layer comprises a plurality of conductive layers sequentially disposed on the base substrate, and
the power supply connection lines and the first power supply lines are disposed in different conductive layers.

9. The display substrate according to claim 8, wherein the at least two signal lines comprise a first connection line and the power supply connection line, and the power supply connection line and the first connection line are disposed in a same conductive layer.

10. The display substrate according to claim 9, wherein
the drive structure layer further comprises a second connection line, the second connection line is connected to the first connection line,
the first connection line is connected to a data signal line, and
the data signal line, the first power supply line, and the second connection line are disposed in a same conductive layer.

11. The display substrate according to claim 1, wherein
the plurality of light emitting units comprises a red light emitting unit emitting red light, a blue light emitting unit emitting blue light, a first green light emitting unit emitting green light, and a second green light emitting unit emitting green light, the red light emitting unit comprises at least a first anode and a first pixel opening exposing the first anode, the blue light emitting unit comprises at least a second anode and a second pixel opening exposing the second anode, the first green light emitting unit comprises at least a third anode and a third pixel opening exposing the third anode, and the second green light emitting unit comprises at least a fourth anode and a fourth pixel opening exposing the fourth anode;
for at least one of the first pixel opening and the second pixel opening, and the at least two signal lines are respectively located at two sides of a geometric center of the pixel opening in second direction.

12. The display substrate according to claim 11, wherein the drive structure layer further comprises a plurality of anode pads, for at least one of the third pixel opening and the fourth pixel opening, an orthographic projection of the pixel opening on the base substrate is at least partially overlapped with an orthographic projection of the anode pads on the base substrate.

13. The display substrate according to claim 12, wherein for at least one of the third pixel opening and the fourth pixel opening, an orthographic projection of the pixel opening on the base substrate is within a range of an orthographic projection of the anode pads on the base substrate.

14. The display substrate according to claim 12, wherein the drive structure layer further comprises a first power supply line, and the anode pads are connected to the first power supply line.

15. The display substrate according to claim 14, wherein on a plane perpendicular to the display substrate, the drive structure layer comprises a plurality of conductive layers disposed sequentially on the base substrate, and the anode pads and the first power supply line are disposed in a same conductive layer.

16. A display apparatus, comprising the display substrate according to claim 1.

17. A preparation method for a display substrate, comprising:
forming a drive structure layer on a base substrate, wherein the drive structure layer comprises a plurality of circuit units and at least two signal lines extending along a first direction, at least one circuit unit comprises a pixel drive circuit;
forming a light emitting structure layer on the drive structure layer, wherein the light emitting structure layer comprises a plurality of light emitting units, at least one light emitting unit comprises an anode and a pixel definition layer disposed on a side of the anode away from the base substrate, the anode is connected to a pixel drive circuit of a corresponding circuit unit, and the pixel definition layer is provided with a pixel opening exposing the anode; and
the drive structure layer further comprises at least two signal lines extending along a first direction, in at least one pixel opening, an orthographic projection of the pixel opening on the base substrate is at least partially overlapped with an orthographic projection of the at least two signal lines on the base substrate, and the at least two signal lines are respectively located at two sides of a geometric center of the pixel opening in a second direction, and the first direction and the second direction intersect.
